(19) United States
(12) Patent Application Publication
(10) Pub. No.: US 2025/0056947 A1
(43) Pub. Date: Feb. 13, 2025

(54) ELECTRONIC APPARATUS AND METHOD OF MANUFACTURING THE SAME

(71) Applicant: Japan Display Inc., Tokyo (JP)

(72) Inventors: Koichi MIYASAKA, Tokyo (JP); Shuichi OSAWA, Tokyo (JP); Yoshikatsu IMAZEKI, Tokyo (JP); Yoichi KAMIJO, Tokyo (JP); Yoshifumi KAMEI, Tokyo (JP)

(73) Assignee: Japan Display Inc., Tokyo (JP)

(21) Appl. No.: 18/795,577

(22) Filed: Aug. 6, 2024

(30) Foreign Application Priority Data
Aug. 10, 2023 (JP) 2023-131079

(51) Int. Cl. H01L 33/62; H01L 27/15; H01L 33/48

(52) U.S. Cl. CPC H01L 33/62; H01L 27/156; H01L 33/486; H01L 2933/0066

(57) ABSTRACT

Performance of an electronic apparatus is improved. A terminal of the electronic apparatus includes: a first metal layer made of aluminum; and a second metal layer which is arranged on the first metal layer, which is bonded to a cap film and which is made of titanium. The cap film includes a metal film which is made of titanium and is bonded to the second metal layer. The metal film includes: a contact portion which totally covers a portion of the metal layer ML3 of the terminal, the portion being exposed at an opening of an insulating layer from the insulating layer; and a peripheral portion which is arranged outside the opening and which continuously surrounds the contact portion in plan view. The insulating layer intervenes between the peripheral portion of the metal film and the terminal.

### CROSS-REFERENCE TO RELATED APPLICATION

The present application claims priority to Japanese Patent Application No. 2023-131079 filed on Aug. 10, 2023, the disclosure of which is incorporated herein by reference.

### TECHNICAL FIELD OF THE INVENTION

The present invention relates to an electronic apparatus and a method of manufacturing the same.

### BACKGROUND OF THE INVENTION

There are electronic apparatuses in each of which electronic components are mounted on a plurality of electrodes arranged on a substrate. For example, Japanese Patent Application Laid-open Publication No. 2014-197619 (Patent Document 1) describes an electronic apparatus in which light emitting diode (LED) elements are mounted on a plurality of electrodes arranged on a substrate.

### SUMMARY OF THE INVENTION

In a case of an electronic apparatus in which an electronic component is mounted on a terminal formed on a substrate, a bump electrode may be formed on the substrate in order to easily connect an electrode of the electronic component and the terminal on the substrate. According to the studies made by the present inventors, from observation of the electronic apparatus on which the electronic component has been mounted, it has been found that voids are formed around the bump electrode.

An objective of the present invention is to provide a technique capable of improving performance of an electronic apparatus.

An electronic apparatus according to one embodiment includes: a first substrate; a first terminal arranged on the first substrate; a first insulating layer which is an inorganic insulating layer made of an inorganic material and which covers the first terminal; a first opening formed in the first insulating layer; a first cap film connected to the first terminal at the first opening; and a first bump electrode electrically connected to the first terminal through the first cap film. The first terminal includes: a first metal layer made of aluminum; and a second metal layer which is arranged on the first metal layer to be in tight contact with the first metal layer, which is bonded to the first cap film at the first opening, and which is made of titanium. The first cap film includes a first metal film which is made of titanium and which is bonded to the second metal layer at the first opening. The first metal film includes: a contact portion which totally covers a portion of the second metal layer of the first terminal, the portion being exposed at the first opening from the first insulating layer; and a peripheral portion which is arranged outside the first opening and which continuously surrounds the contact portion in plan view. The first insulating layer intervenes between the peripheral portion of the first metal film and the first terminal.

A method of manufacturing an electronic apparatus according to another embodiment includes: a step (a) of forming a first terminal on a first substrate; a step (b) of forming a first insulating layer made of an inorganic material to cover the first terminal; a step (c) of forming a first opening in the first insulating layer to expose a part of the first terminal from the first insulating layer; a step (d) of forming a first cap film to cover the first opening; and a step (e) of forming a bump electrode on the first cap film. The step (a) includes: a step (a1) of forming a first metal layer made of aluminum; and a step (a2) of forming a second metal layer made of titanium on the first metal layer to be in tight contact with the first metal layer. The step (d) includes a step (d1) of forming a first metal film which is made of titanium and which is be bonded to the second metal layer at the first opening. The first metal film includes: a contact portion which totally covers a portion of the second metal layer of the first terminal, the portion being exposed at the first opening from the first insulating layer; and a peripheral portion which is arranged outside the first opening and which continuously surrounds the contact portion in plan view. The first insulating layer intervenes between the peripheral portion of the first metal film and the first terminal.

### BRIEF DESCRIPTIONS OF THE DRAWINGS

FIG. 1 is a plan view illustrating a configuration example of a micro-LED display apparatus according to one embodiment of an electronic apparatus.

FIG. 2 is a circuit diagram illustrating a configuration example of a circuit around a pixel of FIG. 1.

FIG. 3 is a transparent enlarged plan view illustrating a peripheral configuration example of LED elements arranged in a plurality of pixels in the display apparatus of FIG. 1.

FIG. 4 is an enlarged cross-sectional view taken along the line A-A of FIG. 3.

FIG. 5 is an enlarged plan view illustrating one of a plurality of terminals of FIG. 3 to be enlarged.

FIG. 6 is an enlarged cross-sectional view taken along the line B-B of FIG. 5.

FIG. 7 is an enlarged cross-sectional view illustrating a study example of FIG. 6.

FIG. 8 is an enlarged cross-sectional view illustrating another study example of FIG. 6.

FIG. 9 is an enlarged cross-sectional view illustrating a different terminal of the two terminals of FIG. 4 from that of FIG. 6 to be enlarged.

FIG. 10 is an explanatory diagram illustrating a flow example of steps of a method of manufacturing a display apparatus according to one embodiment of an electronic apparatus.

FIG. 11 is an enlarged cross-sectional view illustrating an insulating-layer forming step of FIG. 10.

FIG. 12 is an enlarged cross-sectional view illustrating an opening forming step of FIG. 10.

FIG. 13 is an enlarged cross-sectional view illustrating a first-metal-film forming step of FIG. 10.

FIG. 14 is an enlarged cross-sectional view illustrating a second-metal-film forming step of FIG. 10.

FIG. 15 is an enlarged cross-sectional view illustrating a third-metal-film forming step of FIG. 10.

FIG. 16 is an enlarged cross-sectional view illustrating a fourth-metal-film forming step of FIG. 10.

FIG. 17 is an enlarged cross-sectional view illustrating a modification example of FIG. 6.

FIG. 18 is an enlarged cross-sectional view illustrating a modification example of FIG. 9.

FIG. 19 is an explanatory diagram illustrating a flow example of steps of a method of manufacturing a display apparatus according to a modification example of FIG. 10.

FIG. 20 is an enlarged cross-sectional view illustrating a seed-layer forming step of FIG. 19.

FIG. 21 is an enlarged cross-sectional view illustrating a resist-film forming step of FIG. 19.

FIG. 22 is an enlarged cross-sectional view illustrating a second-metal-layer forming step of FIG. 19.

FIG. 23 is an enlarged cross-sectional view illustrating a third-metal-layer forming step of FIG. 19.

FIG. 24 is an enlarged cross-sectional view illustrating a bump-electrode forming step of FIG. 19.

FIG. 25 is an enlarged cross-sectional view illustrating a resist-film removing step of FIG. 19.

FIG. 26 is an enlarged cross-sectional view illustrating a seed-layer removing step of FIG. 19.

### DESCRIPTIONS OF THE PREFERRED EMBODIMENTS

The following is explanation on each embodiment of the present invention with reference to drawings. Note that only one example is disclosed, and appropriate modification with keeping the concept of the present invention which can be easily anticipated by those who are skilled in the art is obviously within the scope of the present invention. Also, in order to make the explanation clear, a width, a thickness, a shape, and others of each portion in the drawings are schematically illustrated more than those in an actual aspect in some cases. However, the illustration is only one example, and does not limit the interpretation of the present invention. In the present specification and each drawing, similar elements to those described earlier for the already-described drawings are denoted with the same or similar reference characters, and detailed description for them is appropriately omitted in some cases.

The following embodiments will be explained while taking a micro-LED display apparatus on which a plurality of micro-LED elements are mounted and taking a bump electrode array apparatus prepared before mounting the micro-LED elements as an electronic apparatus example in which a bump electrode array used for mounting a plurality of electronic components is arranged.

In the present application, the expression “a member A is made of B” may be used for describing a material making a specific member. This means that “a material of the largest amount in weight ratio among materials making a member A is a material B.” Therefore, this meaning may include a case in which the member A is simply made of only B without containing impurities and a case in which the member A contains impurities in addition to B.

### <Electronic Apparatus>

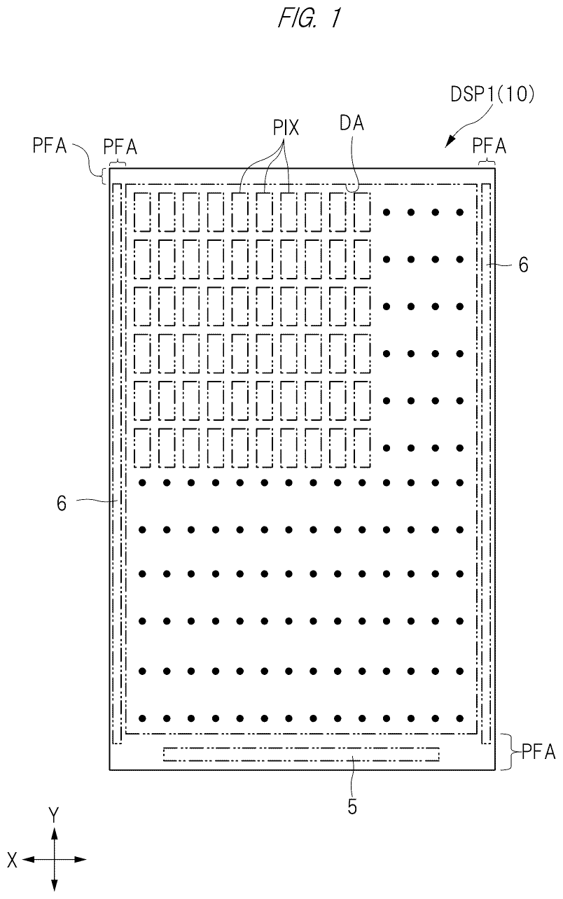

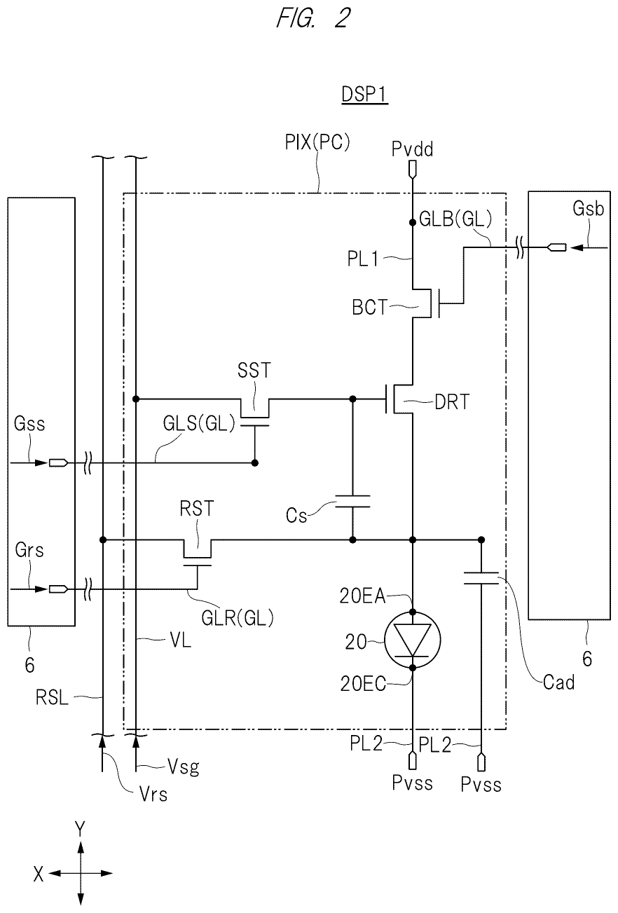

First, a configuration example of a micro-LED display apparatus according to an aspect of the electronic apparatus of the present embodiment will be described. FIG. 1 is a plan view showing a configuration example of the display apparatus according to an embodiment. In FIG. 1, each of a boundary between a display region DA and a peripheral region PFA, a control circuit 5, a drive circuit 6, and a plurality of pixels PIX is illustrated with a dashed double-dotted line. FIG. 2 is a circuit diagram showing a configuration example of a circuit around the pixel shown in FIG. 1. Note that a pixel circuit PC shown in FIG. 2 is illustrated as an example of an equivalent circuit corresponding to one pixel PIX shown in FIG. 1.

FIG. 1 shows an X direction and a Y direction. The X direction and the Y direction cross each other. In an example explained below, the X direction is orthogonal to the Y direction. An X-Y plane including the X direction and the Y direction will be explained below as a plane parallel to a display surface of the display apparatus. In the following explanation, a term “plan view” means viewing of a plane parallel to the X-Y plane unless otherwise particularly stated that the term is to be interpreted in different meaning. Also, as described later, a normal-line direction to the X-Y plane will be explained as a “Z direction” or a thickness direction. The X direction, the Y direction and the Z direction are directions crossing one another, more specifically being orthogonal to one another.

The explanation of the present specification may describe that “A” is “covered” with “B”. This phrase “A is covered with B” means that the entire A overlaps B in plan view that is viewing of the X-Y plane described above. In addition, the phrase “A is covered with B” may be rephrased to be “the entire A overlaps B in the thickness direction (Z direction)” as described above.

As shown in FIG. 1, a display apparatus DSP1 of the present embodiment includes the display region DA, the peripheral region PFA surrounding the display region DA in a frame form, and the plurality of pixels PIX arranged in a matrix form within the display region DA. The display apparatus DSP1 also includes a substrate 10, the control circuit 5 formed on the substrate 10, and the drive circuit 6 formed on the substrate 10.

The control circuit 5 is a control circuit that controls driving of a displaying function of the display apparatus DSP1. For example, the control circuit 5 is a driver IC (Integrated Circuit) mounted on the substrate 10. In the example shown in FIG. 1, the control circuit 5 is arranged along one short side among four sides of the substrate 10. In an example of the present embodiment, the control circuit 5 includes a signal line drive circuit (video driver) that drives video signal lines VL (see FIG. 2) connected to the plurality of pixels PIX. However, the position and configuration example of the control circuit 5 are not limited to the example shown in FIG. 1, and there are various modification examples thereof. For example, in FIG. 1, a circuit board such as a flexible printed board may be connected to the position shown as the control circuit 5, and the above-described driver IC may be mounted on the circuit board. In addition, for example, the signal line drive circuit that drives the video signal lines VL may be formed separately from the control circuit 5.

The drive circuit (scan driver) 6 is a circuit that drives scan signal lines GLB, GLR and GLS (see FIG. 2) of the plurality of pixels PIX. The drive circuit 6 drives the plurality of scan signal lines, based on a control signal from the control circuit 5. In the example shown in FIG. 1, the drive circuit 6 is arranged along each of two long sides among four sides of the substrate 10. In the example shown in FIG. 1, the display region DA is arranged between two drive circuits 6 in plan view. However, the position and configuration example of the drive circuit 6 are not limited to the example shown in FIG. 1, and there are various modification examples thereof. For example, in FIG. 1, a circuit board such as a flexible printed board may be connected to the position shown as the control circuit 5, and the above-described drive circuit 6 may be mounted on the circuit board.

Next, a configuration example of the pixel circuit PC for driving the pixel PIX shown in FIG. 1 will be described with reference to FIG. 2. Note that one pixel circuit PC for driving one pixel is exemplified as a representative example and illustrated in FIG. 2. Each of the plurality of pixels PIX shown in FIG. 1 includes the same circuit as the pixel circuit PC shown in FIG. 2. The pixel circuit PC is a voltage signal type circuit that controls a light emitting state of an LED element (inorganic light emitting diode element, diode element) 20 in accordance with a video signal Vsg supplied from the control circuit 5 (see FIG. 1).

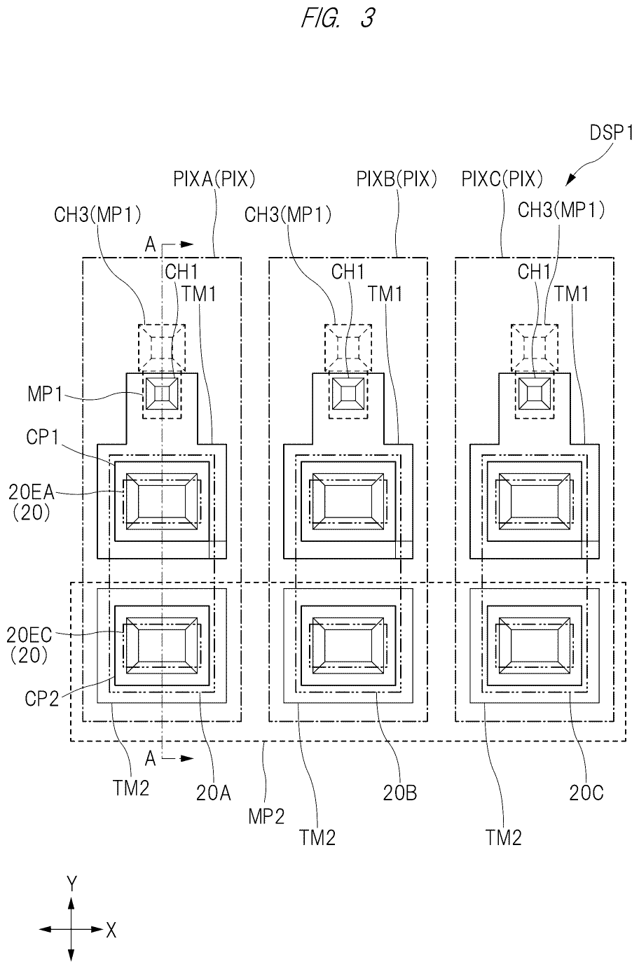

As shown in FIG. 2, the pixel PIX includes the LED element 20. The LED element 20 is the micro light-emitting diode described above. The LED element 20 includes an anode electrode 20EA (see FIG. 3 described later) and a cathode electrode 20EC (see FIG. 3 described later).

The display region DA of the display apparatus DSP1 includes a plurality of types of wirings. These wirings include the plurality of scan signal lines GLS, GLR and GLB, the plurality of video signal lines VL, a plurality of power supply lines PL1, a plurality of power supply lines PL2 and a plurality of reset wirings RSL.

The scan signal lines GLS, GLR and GLB extend in the X direction, and are connected to the drive circuit 6. For example, as shown in FIG. 1, the scan signal lines GLS, GLR and GLB for driving the even-numbered pixel PIX of the pixels PIX arranged in the Y direction are connected to one of the drive circuits 6 while the scan signal lines GLS, GLR and GLB for driving the odd-numbered pixel PIX are connected to the other of the drive circuits 6. As another example, for example, any of the scan signal lines GLS, GLR and GLB may be connected to one of the drive circuits 6 while the rest of the scan signal lines GLS, GLR and GLB may be connected to the other of the drive circuits 6, such that all the scan signal lines GLS and GLR are connected to one of the drive circuits 6 while all the scan signal lines GLB are connected to the other of the drive circuits 6.

The video signal lines VL, the power supply lines PL1 and PL2 and the reset wiring RSL extend in the Y direction. The video signal line VL is connected to the control circuit 5 (see FIG. 1). A video signal Vsg and an initialization signal are supplied from the control circuit 5 to the video signal line VL. A high potential Pvdd is supplied from the control circuit 5 to the power supply line PL1. A low potential Pvss lower than the high potential Pvdd is supplied from the control circuit 5 to the power supply line PL2. A rest signal Vrs is supplied from the control circuit 5 to the reset wiring RSL.

The control circuit 5 outputs a start pulse signal or a clock signal not illustrated to the drive circuit 6. The drive circuit 6 includes a plurality of shift register circuits, sequentially transfers the start pulse signal to a shift register circuit of a next stage in response to the clock signal, and sequentially supplies the scan signal to each of the scan signal lines GLS, GLR and GLB.

The pixel circuit PC controls the LED element 20 in response to the video signal Vsg supplied to the video signal line VL. In order to achieve such control, the pixel circuit PC according to the present embodiment includes a rest transistor (switching element) RST, a pixel selection transistor (switching element) SST, an output transistor (switching element) BCT, a drive transistor (switching element) DRT, a holding capacitance Cs and an auxiliary capacitance Cad. The auxiliary capacitance Cad is an element for adjusting a light-emitting current volume, and may be unnecessary depending on cases.

Each of the rest transistor RST, the pixel selection transistor SST, the output transistor BCT and the drive transistor DRT is a switching element made of a Thin Film Transistor (TFT). A conductivity type of the thin film transistor is not particularly limited. For example, each of all transistors may be made of an N-channel type TFT, or at least one of these transistors may be made of a P-channel type TFT.

In the present embodiment, the rest transistor RST, the pixel selection transistor SST, the output transistor BCT and the drive transistor DRT are formed by the same step to have the same layer structure as one another, and have a bottom gate structure in which polycrystal silicon is used for a semiconductor layer. As another example, the rest transistor RST, the pixel selection transistor SST, the output transistor BCT and the drive transistor DRT may have a top gate structure. Note that oxide semiconductor, polycrystal GaN semiconductor or others may be used for the semiconductor layer.

Each of the rest transistor RST, the pixel selection transistor SST, the output transistor BCT and the drive transistor DRT includes a source electrode, a drain electrode and a gate electrode. The gate electrode included in each transistor is also referred to as control electrode. The source electrode and the drain electrode included in each transistor is simply referred to as electrode.

The drive transistor DRT and the output transistor BCT are connected in series to the LED element 20, between the power supply lines PL1 and PL2. The high potential Pvdd supplied to the power supply line PL1 is set to, for example, 10 V, and the low potential Pvss supplied to the power supply line PL2 is set to, for example, 1.5 V.

The drain electrode of the output transistor BCT is connected to the power supply line PL1. The source electrode of the output transistor BCT is connected to the drain electrode of the drive transistor DRT. The gate electrode of the output transistor BCT is connected to the scan signal line GLB. The output transistor BCT is turned ON/OFF by a control signal Gsb supplied to the scan signal line GLB. In this case, “ON” represents an electrical conduction state, and “OFF” represents an electrical non-conduction state. The output transistor BCT controls light emitting time of the LED element 20, based on the control signal Gsb.

The source electrode of the drive transistor DRT is connected to one electrode (in this case, the anode electrode 20EA) of the LED element 20. The other electrode (in this case, the cathode electrode 20EC) of the LED element 20 is connected to the power supply line PL2. The drive transistor DRT outputs a drive electric current depending on the video signal Vsg to the LED element 20.

The source electrode of the pixel selection transistor SST is connected to the video signal line VL. The drain electrode of the pixel selection transistor SST is connected to the gate electrode of the drive transistor DRT. The gate electrode of the pixel selection transistor SST is connected to the scan signal line GLS functioning as a gate wiring for signal writing control. The pixel selection transistor SST is turned ON/OFF by a control signal Gss supplied from the scan signal line GLS to switch a state between the pixel circuit PC and the video signal line VL to a connection state or a disconnection state. In other words, when the pixel selection transistor SST is turned ON, the video signal Vsg of the video signal line VL or the initialization signal is supplied to the gate electrode of the drive transistor DRT.

The source electrode of the reset transistor RST is connected to the reset wiring RSL. The drain electrode of the reset transistor RST is connected to the source electrode of the drive transistor DRT and the anode of the LED element 20. The gate electrode of the reset transistor RST is connected to the scan signal line GLR functioning as a gate wiring for rest control. The reset transistor RST is turned ON/OFF by a control signal Grs supplied from the scan signal line GLR. When the reset transistor RST is turned ON, potentials of the source electrode of the drive transistor DRT and the anode of the LED element 20 can be reset by a reset signal Vrs of the reset wiring RSL. In other words, the reset wiring RSL is a wiring for resetting the voltage of the LED element 20.

The holding capacitance Cs is connected between the gate electrode and the source electrode of the drive transistor DRT. The auxiliary capacitance Cad is connected between the source electrode of the drive transistor DRT and the power supply line PL2.

The drive circuit 6 sequentially supplies the control signals Gss, Grs and Gsb to the scan signal lines GLS, GLR and GLB of each line (a series of pixels PIX in the X direction), based on the start pulse signal and the clock signal. The control circuit 5 sequentially supplies the video signal Vsg and the initialization signal to each video signal line VL, based on the signal supplied from the control circuit 5 shown in FIG. 2. The electric charge held in the holding capacitance Cs by the supply of the video signal Vsg is initialized by the supply of the initialization signal.

In such a configuration described above, the pixel circuit PC is driven by the control signals Gss, Grs and Gsb supplied to the scan signal lines GLS, GLR and GLB, and the LED element 20 emits the light having a luminance depending on the video signal Vsg of the video signal line VL.

### <Peripheral Structure of LED Element>

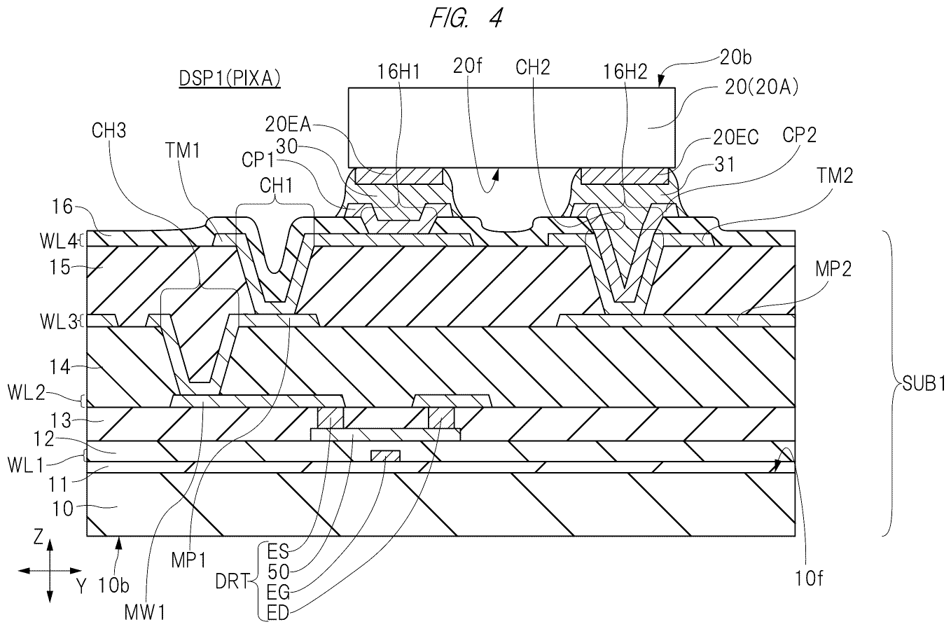

Next, a peripheral structure of the LED element arranged in the pixel PIX shown in FIG. 1 will be explained. FIG. 3 is an enlarged transparent plan view showing an example of the peripheral structure of the LED element arranged in each of the plurality of pixels of the display apparatus shown in FIG. 1. FIG. 4 is an enlarged cross-sectional view taken along a line A-A in FIG. 3.

In FIG. 3, each of the conductor pattern and a cap film CP1 arranged on the wiring layer WL4 shown in FIG. 4 is illustrated with a solid line. In FIG. 3, each outline of the LED element 20 and the electrode included in the LED element 20 is illustrated with a dashed double-dotted line. The pixel PIXA, the pixel PIXB, and the pixel PIXC shown in FIG. 3 have the same structure as one another. Therefore, FIG. 4 shows the structure of the pixel PIXA (see FIG. 3) as a representative example. However, the pixel PIXB and the pixel PIXC shown in FIG. 3 also have the same cross-sectional structure.

In the following explanation, the terms “terminal TM1” and “terminal TM2” are used for the explanation. The term “terminal” means a conductor pattern including a terminal portion used for electrical connection of an external device, and can be rephrased and applied as “terminal pattern”.

The pixel circuit PC shown in FIG. 2 is the circuit corresponding to each of the pixel PIXA, the pixel PIXB and the pixel PIXC shown in FIG. 3. Therefore, each of the pixel PIXA, the pixel PIXB, and the pixel PIXC shown in FIG. 3 includes the reset transistor RST, the pixel selection transistor SST, the output transistor BCT, and the drive transistor DRT described with reference to FIG. 2. Similarly, each of the pixel PIXA, the pixel PIXB and the pixel PIXC shown in FIG. 3 includes the holding capacitance Cs and the auxiliary capacitance Cad described with reference to FIG. 2.

As shown in FIG. 4, the display apparatus DSP1 includes a substrate structure SUB1 and the LED element (inorganic light emitting diode element) 20 mounted on the substrate structure SUB1. The substrate structure SUB1 of the display apparatus DSP1 includes a plurality of insulating layers arranged between a plurality of wiring layers. The LED element 20 is mounted on the wiring layer WL4 arranged in the topmost layer among the plurality of wiring layers.

The substrate structure SUB1 of the display apparatus DSP1 includes a substrate 10. The substrate 10 has a surface 10f and a surface 10b opposite to the surface 10f. A plurality of wiring layers and a plurality of insulating layers are stacked on the surface 10f of the substrate 10. The substrate 10 is, for example, a glass substrate made of glass. However, there are various modification examples of a material configuring the substrate 10. For example, a resin substrate made of resin may be used.

The substrate structure SUB1 includes a transistor as a switching element. In FIG. 4, the drive transistor DRT is illustrated as an example of the switching element arranged on the substrate 10. However, on the substrate 10 (more specifically, on the insulating layer 11), each of the reset transistor RST, the pixel selection transistor SST, the output transistor BCT, and the drive transistor DRT described with reference to FIG. 2 is arranged. Each of the reset transistor RST, the pixel selection transistor SST, the output transistor BCT, and the drive transistor DRT shown in FIG. 2 has the same structure as that of the drive transistor DRT shown in FIG. 4 described later.

As shown in FIG. 3, the display apparatus DSP1 includes a plurality of LED elements 20. Among the plurality of LED elements 20 of the display apparatus, FIG. 3 shows an LED element 20A, an LED element 20B next to the LED element 20A, and an LED element 20C next to the LED element 20B.

As shown in FIG. 4, the LED element 20 has a surface 20f and a surface 20b opposite the surface 20f. The LED element 20 includes a plurality of (in FIG. 3, two) electrodes arranged on the surface 20f. The plurality of electrodes of the LED element 20 include an anode electrode 20EA and a cathode electrode 20EC. The anode electrode 20EA is electrically connected to the terminal TM1 through the bump electrode 30. The cathode electrode 20EC is electrically connected to the terminal TM2 through the bump electrode 31.

Among the conductor patterns included in the substrate structure SUB1, the terminal TM1 and the terminal TM2 are conductor patterns each including a portion that functions as a “terminal” used for electrically connecting the LED element 20 and the substrate structure SUB1.

The display apparatus DSP1 displays images by driving each of the plurality of LED elements 20 mounted on the substrate structure SUB1.

In the example shown in FIG. 4, the plurality of wiring layers included in the display apparatus DSP1 include a wiring layer WL4, a wiring layer WL3, a wiring layer WL2 and a wiring layer WL1, which are stacked in this order from the wiring layer WL4 to the substrate 10. The plurality of insulating layers included in the display apparatus DSP1 include insulating layers 11, 12, 13, 14, and 15, which are stacked in this order from the surface 10f of the substrate 10.

The insulating layer 11 is a base layer of the thin-film transistor, and is an inorganic insulating layer made of an inorganic material. The wiring layer WL1 is arranged on the insulating layer 11, and is covered with the insulating layer 12. The conductor pattern formed in the wiring layer WL1 includes the gate electrode EG shown in FIG. 4 and the scan signal lines GLB, GLS, and GLR described with reference to FIG. 2. The insulating layer 12 is also an inorganic insulating layer made of an inorganic material. A portion of the insulating layer 12, the portion being arranged between the gate electrode EG of the transistor and the semiconductor layer 50, functions as a gate insulating film.

The drive transistor DRT including the gate electrode EG includes the semiconductor layer 50, the gate electrode EG, the source electrode ES, and the drain electrode ED. In the example shown in FIG. 4, the thin-film transistor with the bottom gate structure is shown as an example. However, the top gate structure may be used as described above. The gate electrode EG is arranged on the insulating layer 11. The semiconductor layer 50 is arranged on the insulating layer 12. One portion of the semiconductor layer 50 corresponds to a source region, and the source electrode ES is connected to the source region. The other portion of the semiconductor layer 50 corresponds to a drain region, and the drain electrode ED is connected to the drain region. A region between the source region and the drain region functions as a channel region.

The wiring layer WL2 is arranged on the insulating layer 13 covering the drive transistor DRT. The insulating layer 13 is an inorganic insulating layer made of an inorganic material. The conductor pattern formed in the wiring layer WL2 includes a wiring connected to each of the plurality of transistors. For example, as shown in FIG. 4, a wiring pattern MW1 connected to the source electrode ES of the drive transistor DRT is included in the wiring layer WL2. The conductor pattern formed in the wiring layer WL2 includes the video signal line VL, the power supply line PL1, the power supply line PL2, and the reset wiring RSL shown in FIG. 2.

The wiring layer WL2 includes the wiring pattern MW1 electrically connected to the conductor pattern MP1 through a contact hole CH3 formed in the insulating layer 14 and electrically connected to the electrode (source electrode ES) of the drive transistor DRT.

Each of the insulating layer 14 covering the wiring layer WL2 and the insulating layer 15 stacked on the insulating layer 14 is an organic insulating film made of an organic material. The insulating layer 14 is an insulating layer arranged between the wiring layer WL2 and the wiring layer WL3. The insulating layer 15 is an insulating layer arranged between the wiring layer WL3 and the wiring layer WL4. As shown in FIG. 4, a contact hole is used for electrical connection between the wiring layer WL2 and the wiring layer WL3 and electrical connection between the wiring layer WL3 and the wiring layer WL4. The organic insulating layer has better embeddability in the opening (such as the contact hole) than that of the inorganic insulating layer. In other words, in the case of the organic insulating layer, even if the base member has an opening, its upper surface can be easily flattened. Therefore, each of the insulating layer 14 and the insulating layer 15 including a lot of contact holes formed therein is made of an organic material. For example, an acrylic resin can be exemplified as the organic material configuring the insulating layer 14 and the insulating layer 15.

FIG. 4 shows contact holes CH1, CH2, and CH3 among the lot of contact holes included in the substrate structure SUB1. The contact hole CH1 is an opening for connecting the terminal TM1 and the conductor pattern MP1 of the wiring layer WL3. The contact hole CH2 is an opening for connecting the terminal TM2 and the conductor pattern MP2 of the wiring layer WL3. The contact hole CH3 is an opening for connecting the conductor pattern MP1 of the wiring layer WL3 and the wiring pattern MW1 of the wiring layer WL2.

The wiring layer WL3 includes a conductor pattern MP1 electrically connected to the terminal TM1 through the contact hole CH1 formed in the insulating layer 15 and a conductor pattern MP2 made of the same metal as that of the conductor pattern MP1 and electrically connected to the terminal TM2 through the contact hole CH2 formed in the insulating layer 15.

The conductor pattern MP1 has a flat portion connected to the terminal TM1 at a bottom surface of the contact hole CH1 and a contact portion embedded in the contact hole CH3 and connected to the wiring layer WL2. As shown in FIG. 3, the conductor pattern MP2 is a large-area pattern that spreads over the plurality of pixels PIX.

Each of the conductor pattern MP1, the conductor pattern MP2, the terminal TM1, and the terminal TM2 shown in FIG. 4 is made of, for example, the same metal material as one another. In the present embodiment, although described in detail later, each of the conductor pattern MP1, the conductor pattern MP2, the terminal TM1, and the terminal TM2 is a stacking film of a titanium layer made of titanium, an aluminum layer made of aluminum, and a titanium layer made of titanium.

The wiring layer WL4 is a wiring layer arranged in the topmost wiring layer among the plurality of wiring layers. The wiring layer WL4 includes the terminal (conductor pattern) TM1 electrically connected to the anode electrode 20EA of the LED element 20A and the terminal (conductor pattern) TM2 electrically connected to the cathode electrode 20EC of the LED element 20A.

The wiring layer WL4 is covered with an insulating layer 16 made of an inorganic material. The insulating layer 16 is an inorganic insulating layer made of, for example, silicon nitride of silicon oxide. Each of the terminals TM1 and TM2 is covered with the insulating layer 16.

Specifically, the terminal TM1 has a terminal portion (also called a flat portion) connected to a cap film CP1 at the opening of the insulating layer 16, and a contact portion embedded in the contact hole CH1 and connected to the wiring layer WL3. The contact portion is covered with the insulating layer 16. Similarly, the terminal TM2 has a terminal portion connected to a cap film CP2 at the opening of the insulating layer 16 and a contact portion embedded in the contact hole CH2 and connected to the wiring layer WL3. The contact portion is covered with the insulating layer 16. Each of the terminals TM1 and TM2 is an external terminal of the substrate structure SUB1.

An opening 16H1 is formed in a part of the insulating layer 16. The terminal TM1 arranged in the wiring layer WL4 is connected to the cap film CP1 at the opening 16H1 formed in the insulating layer 16. Similarly, the terminal TM2 arranged in the wiring layer WL4 is connected to the cap film CP2 at an opening 16H2 formed in the insulating layer 16.

Specifically, the cap film CP1 and the terminal TM1 are bonded at the bottom of the opening 16H1. The cap film CP2 and the terminal TM2 are bonded at the bottom of the opening 16H2. The bottom of the opening 16H1 is a portion of the opening 16H1, the portion penetrating through the insulating layer 16, in other words, a part of the terminal TM1 being exposed from the insulating layer 16.

As detailed later, each of the cap film CP1 and the cap film CP2 includes a titanium film made of titanium. The titanium film is arranged at the bonding boundary with the terminal TM1 or the terminal TM2.

A bump electrode 30 is electrically connected to the terminal TM1 through the cap film CP1. The bump electrode 31 is electrically connected to the terminal TM2 through the cap film CP2. The anode electrode 20EA of the LED element 20A is electrically connected to the terminal TM1 through the bump electrode 30 and the cap film CP1. The cathode electrode 20EC of the LED element 20A is electrically connected to the terminal TM2 through the bump electrode 31 and the cap film CP2.

Each of the bump electrode 30 and the bump electrode 31 is made of, for example, tin.

### <Cap Film and Bump Electrode>

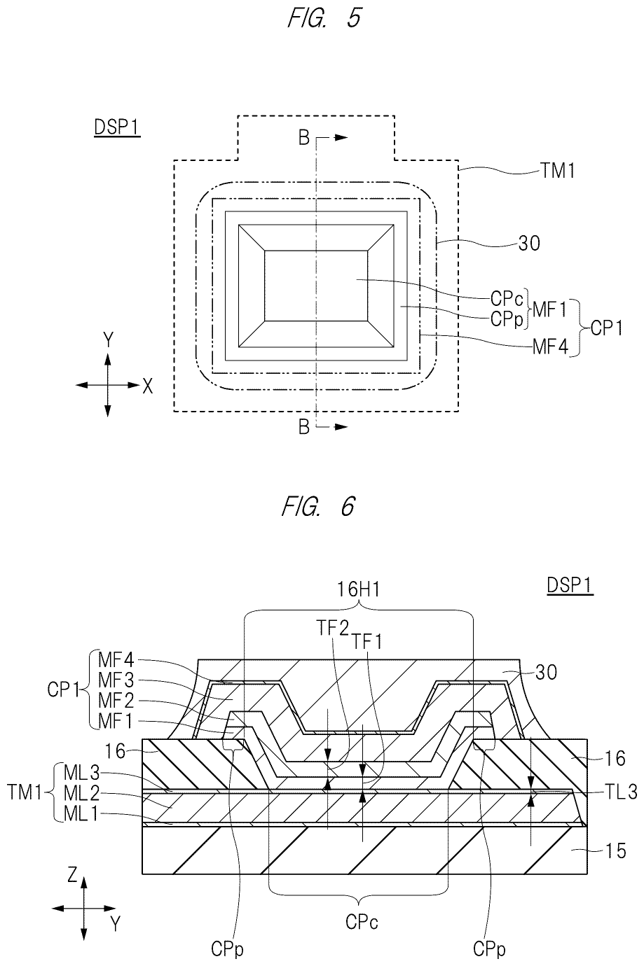

FIG. 5 is an enlarged plan view illustrating one of a plurality of terminals of FIG. 3 to be enlarged. FIG. 6 is an enlarged cross-sectional view taken along the line B-B of FIG. 5. In FIG. 5, the metal film MF1 arranged in the lowermost layer among the plurality of metal films of the cap film CP1 of FIG. 6 is illustrated with a solid line. In FIG. 5, each of an outline of the metal film MF4 arranged in the uppermost layer among the metal films of the cap film CP1 of FIG. 6 and an outline of the bump electrode 30 is illustrated with a dashed double-dotted line. In FIG. 5, an outline of the terminal TM1 is illustrated with a dotted line.

The terminal TM1 includes a metal layer ML1, a metal layer ML2, and a metal layer ML3 which are stacked on the insulating layer 15 made of an organic material in this order as illustrated in FIG. 6. The metal layer ML1 is made of titanium. The metal layer ML1 is arranged on the insulating layer 15 to be in tight contact with the insulating layer 15. The metal layer ML2 is made of aluminum. The metal layer ML2 is arranged on the metal layer ML1 to be in tight contact with the metal layer ML3. The metal layer ML3 is made of titanium. The metal layer ML3 is arranged on the metal layer ML2 to be in tight contact with the metal layer ML2. The metal layer ML3 is bonded to the cap film CP1 at the bottom of the opening 16H1.

The metal layer ML2 is a main conductive layer in the terminal TM1 that is the conductor pattern. Thus, the thickness (for example, 500 nm) of the metal layer ML2 is larger than the thickness (for example, 50 nm) of the metal layer ML1 and the thickness (for example, 50 nm) of the metal layer ML3.

Aluminum making the metal layer ML2 is preferable as a material having high electric conductivity, being easily patterned, or making a wiring pattern or a terminal pattern. However, it is preferable that a titanium film is arranged to be in tight contact with the metal layer ML3 in order to suppress damage on wiring patterns or electromigration due to stress caused by thermal expansion of the wiring patterns. The example of FIG. 6 shows that the metal layer ML2 is sandwiched between the metal layer ML1 and the metal layer ML3. However, the metal layer ML1 may not be provided in a modification example.

The cap film CP1 includes the metal film MF1 made of titanium and bonded to the metal layer ML3 at the bottom of the opening 16H1. In the example of FIG. 6, the cap film CP1 includes a metal film MF2, a metal film MF3, and the metal film MF4 which are stacked on the metal film MF1. The metal film MF2, the metal film MF3, and the metal film MF4 will be described in detail below.

The metal film MF1 includes a contact portion CPc totally covering a portion of the metal layer ML3 of the terminal TM1 of FIG. 6, the portion being exposed from the insulating layer 16 at the bottom of the opening 16H1. The metal film MF1 includes a peripheral portion CPp arranged outside the opening 16H1 to continuously surround the contact portion CPc in plan view as illustrated in FIG. 5. The phrase “to continuously surround the contact portion CPc in plan view” means that the peripheral portion CPp is not separated in the middle as illustrated in FIG. 5. As illustrated in FIG. 6, the metal film MF1 includes a portion extending along a side surface of the opening 16H1 between the contact portion CPc and the peripheral portion CPp in cross-sectional view. Thus, the contact portion CPc separate from the peripheral portion CPp.

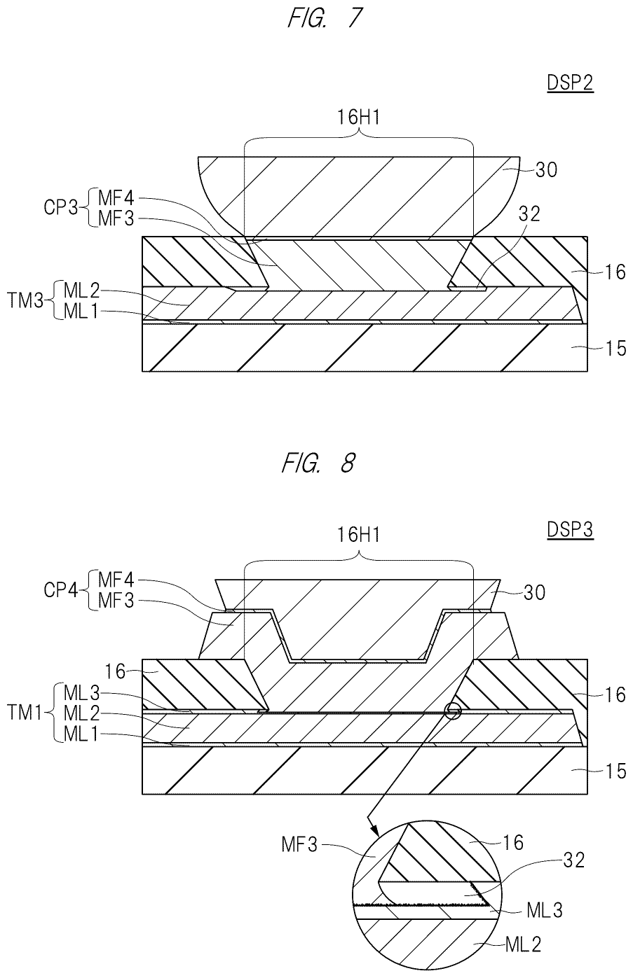

As illustrated in FIG. 6, the insulating layer 16 intervenes between the peripheral portion CPp of the metal film MF1 and the terminal TM1. A study example of FIG. 6 will be described below with reference to FIGS. 7 and 8. Each of FIGS. 7 and 8 is an enlarged cross-sectional view of the study example of FIG. 6.

The terminal TM3 of the display apparatus DSP2 of FIG. 7 is different in configuration from the terminal TM1 of FIG. 6. A cap film CP3 of the display apparatus DSP2 is different in configuration from the cap film CP1 of FIG. 6.

The terminal TM3 of FIG. 7 is a stacked film including the metal layer ML1 made of titanium and the metal layer ML2 made of aluminum. The metal layer ML2 of the stacked metal layers is arranged at the bonding boundary with the cap film CP3. The cap film CP3 of FIG. 7 is a stacked film including the metal film MF3 made of copper and the metal film MF4 made of nickel. The metal film MF3 of the stacked metal films is arranged at the bonding boundary with the terminal TM3. That is, in the study example of FIG. 7, aluminum and copper are bonded at the bonding boundary between the terminal TM3 and the cap film CP3.

In steps of manufacturing the display apparatus DSP2, a step of forming the cap film CP3 on the terminal TM3 is performed as follows. That is, after the terminal TM3 is formed, the insulating layer 16 is formed to cover the terminal TM3. Next, an opening is formed to expose a part of the terminal TM3 from the insulating layer 16. Next, the aluminum oxide film formed on the surface of the metal layer ML2 exposed from the opening of the insulating layer 16 is removed. To a method of removing the aluminum oxide film, for example, so-called a zincate treatment is applicable.

Next, the metal film MF3 of the cap film CP3 is formed on the surface of the metal layer ML2 exposed from the opening of the insulating layer 16 by an electroplating method. According to the studies made by the present inventors, it has been found that a part of the metal layer ML2 is eroded by a copper plating solution in a plating step of forming the metal film MF3. The metal film MF3 made of copper is preferably thick in order to reduce a resistance of a portion electrically connecting the bump electrode 30 and the terminal TM3.

However, since a part of the metal layer ML2 is eroded by the copper plating solution as described above, the thicker metal film MF3 accelerates the erosion more to form voids 32 between the insulating layer 16 and the metal layer ML2 as illustrated in FIG. 7. During the steps of manufacturing the display apparatus DSP2 or at the time of application of a temperature cycle load to the completed display apparatus DSP2, gas (such as air) inside the voids 32 repeatedly expands or shrinks. Thus, stress is applied to the members around the voids 32. The insulating layer 16 may be broken, or the bonding boundary between the terminal TM3 and the cap film CP3 may be peeled off, depending on the degree of the stress. That is, since the voids 32 are caused in the display apparatus DSP2, there is a risk of reduction in reliability of the electric connection around the bump electrode 30.

Next, a cap film CP4 of a display apparatus DSP3 of FIG. 8 is different in configuration from the cap film CP1 of FIG. 6.

The metal layer ML3 made of titanium is arranged at the bonding boundary with the cap film CP4 in the display apparatus DSP3. Thus, in the step of forming the metal film MF3 made of copper, the metal layer ML2 can be prevented from being partially eroded by the copper plating solution. To a method of forming the metal film MF3, the following method is applicable.

That is, first, a copper seed layer is formed on the surface of the insulating layer 16 and the surface of the terminal TM1 exposed at the opening from the insulating layer 16 by a sputtering method. Next, a resist mask not illustrated is formed to cover the copper seed layer, and then, an opening is formed in the resist mask by photolithography. Next, a copper film is grown on the copper seed layer exposed at the opening in the resist mask from the resist mask by, for example, an electroplating method. Then, the metal film MF4 made of nickel and the bump electrode 30 made of tin are formed on the copper film by use of the opening of the resist mask. Then, parts of the resist mask and the copper seed layer, which do not overlap the bump electrode 30, are removed to provide the bump structure of the display apparatus DSP3 illustrated in FIG. 8.

However, in the display apparatus DSP3, different types of metals are bonded at the bonding boundary between the terminal TM1 and the cap film CP4. Thus, it is necessary to sufficiently perform a processing for removing the titanium oxide film or contaminants such as carbon before forming the metal film MF3 of the cap film CP4.

For example, the following method can be exemplified as the process for removing the titanium oxide film or contaminants such as carbon. That is, process gas (such as argon gas) is introduced into a vacuum container in which a substrate to be processed is arranged. By application of a voltage to a portion to be processed (the terminal TM1 in this example) in the substrate to be processed under this state, glow discharge is generated, and plasma caused by the glow discharge collides with the portion to be processed. By the collision energy, the titanium oxide film, carbon, or the like can be removed. This method will be referred to as bias sputtering method below.

In the bias sputtering method, by adjusting power to be applied and a pressure of the process gas, energy of the plasma colliding with the portion to be processed can be adjusted. Since the display apparatus DSP3 employs the bias sputtering method as a preprocessing for bonding the different types of metals, the plasma with a certain high amount of energy needs to collide. Thus, the voids 32 as illustrated in FIG. 8 to be enlarged may be formed between the insulating layer 16 and the metal layer ML3.

As described above, when the metal film MF3 is formed by use of the copper seed layer, the copper seed layer is removed by etching in a step of removing the copper seed layer around the bump electrode 30. At this time, depending on the degree of etching, there is concern that a part of the metal film MF3 is etched while a part of the metal layer ML3 of the terminal TM1 is exposed. In this case, as similar to the voids 32 described with reference to FIG. 7, a gap formed between the metal film MF3 and the insulating layer 16 may cause the decrease in the reliability of electric connection of the display apparatus DSP3.

In consideration of the above description, the display apparatus DSP1 of FIG. 6 is more excellent in the following points than the display apparatus DSP2 of FIG. 7 and the display apparatus DSP3 of FIG. 8.

First, the metal layer ML3 made of titanium is arranged at the bonding boundary with the cap film CP1 of the terminal TM1 of the display apparatus DSP1. Thus, even if the step of forming the metal film MF3 made of copper in the step of forming the cap film CP1 employs the electroplating method, the metal layer ML2 can be prevented from being partially eroded by the copper plating solution.

Also, the cap film CP1 includes the metal film MF1 made of titanium as similar to the metal layer ML3, at the bonding boundary with the terminal TM1. Thus, damage on the metal layer ML3 in the preprocessing step (the step of removing the titanium oxide film) performed before the step of forming the metal film MF1 may be reduced.

For example, even if the metal film MF1 is formed while the titanium oxide film is formed on the surface of the metal film MF1, the bonding strength can be increased. Also, if the titanium oxide film is thick, the bias sputtering may be performed. However, the titanium oxide film does not need to be completely removed in the steps of manufacturing the display apparatus DSP1, the collision of the plasma with the terminal TM1 can be adjusted with energy preventing the formation of the voids 32 of FIG. 8. Consequently, the voids 32 illustrated in FIGS. 7 and 8 can be prevented from being formed.

As described above, the metal film MF1 includes the contact portion CPc totally covering the portion of the metal layer ML3 of the terminal TM1 of FIG. 6, the portion being exposed at the bottom of the opening 16H1 from the insulating layer 16. The metal film MF1 includes the peripheral portion CPp which is arranged outside the opening 16H1 to continuously surround the contact portion CPc in plan view as illustrated in FIG. 5. In other words, the bottom and the periphery of the opening 16H1 are covered with the metal film MF1 made of titanium.

Therefore, even if the copper film is more removed in the step of removing the copper seed layer at the time of the formation of the metal film MF3 by use of the copper seed layer, no gap is formed between the insulating layer 16 and the metal film MF1.

As described above, the display apparatus DSP1 according to the present embodiment is more excellent than the display apparatus DSP2 of FIG. 7 and the display apparatus DSP3 of FIG. 8 in that the decrease in the reliability of connection caused by the voids 32 (or the gap) illustrated in FIGS. 7 and 8 can be prevented.

In the example of FIG. 6, a thickness TF1 of the metal film MF1 of the cap film CP1 is larger than a thickness TL3 of the metal layer ML3 of the terminal TM1. The thickness of the lowermost metal film MF1 arranged in the cap film CP1 is preferably large in order to suppress the damage on the metal film MF1.

The cap film CP1 includes the metal film MF2 stacked on the metal film MF1. The metal film MF2 is made of aluminum. Although not illustrated, in a modification example of the example of FIG. 6, the bump electrode 30 may be formed on the metal film MF1 while only the metal film MF1 is used as the cap film CP1. Alternatively, in a modification example as described later, the metal film MF3 made of copper may be stacked on the metal film MF1 to be in tight contact therewith.

As described in the example of FIG. 6, since the metal film MF2 made of aluminum intervenes between the metal film MF3 made of copper and the metal film MF1 made of titanium, the metal film MF3 can be directly formed on the metal film MF2 by an electroplating method. The metal film MF2 is made of a metal with higher electric conductivity than that of titanium making the metal film MF1. Thus, the impedance of the path electrically connecting the bump electrode 30 and the terminal TM1 can be made lower than that in the case in which only the metal film MF1 is used as the cap film CP1.

The thickness TF1 of the metal film MF1 of the cap film CP1 is smaller than a thickness TF2 of the metal film MF2 of the cap film CP1. As described above, the thickness TF2 of the metal film MF2 is preferably larger than the thickness TF1 of the metal film MF1 in order to decrease the impedance of the path electrically connecting the bump electrode 30 and the terminal TM1.

In the example of FIG. 6, the cap film CP1 includes the metal film MF3 stacked on the metal film MF2. The metal film MF3 is made of copper and totally covers the metal film MF1 and the metal film MF2. Copper is higher in electric conductivity than aluminum. Thus, when the metal film MF3 made of copper intervenes between the bump electrode 30 and the terminal TM1, the impedance of the path electrically connecting the bump electrode 30 and the terminal TM1 can be further decreased.

In the example of FIG. 6, the cap film CP1 further includes the metal film MF4 stacked on the metal film MF3. A part of the metal film MF1 is exposed from the metal film MF2. The metal film MF4 is made of nickel and totally covers the metal film MF3.

Since the metal film MF4 made of nickel is formed in the uppermost layer of the cap film CP1, the bonding strength between the bump electrode 30 made of tin and the cap film CP1 can be improved.

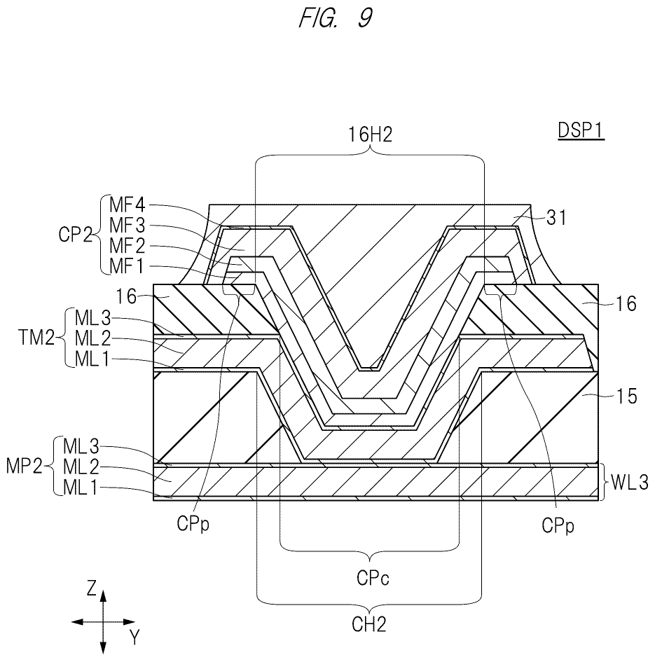

The terminal TM2 illustrated in FIG. 4 is similar to the terminal TM1 illustrated in FIG. 6 except that the terminal TM2 is formed at a position overlapping the contact hole CH2 as illustrated in FIG. 9. FIG. 9 is an enlarged cross-sectional view illustrating a different terminal of the two terminals illustrated in FIG. 4 from that of FIG. 6 to be enlarged.

As illustrated in FIG. 9, a part of the terminal TM2 is connected to the conductor pattern MP2 arranged in the wiring layer WL3. Specifically, the terminal TM2 is bonded to the conductor pattern MP2 at the bottom of the contact hole CH2 formed in the insulating layer 15.

Each of the terminal TM2 and the conductor pattern MP2 includes the metal layer ML1, the metal layer ML2, and the metal layer ML3 which are sequentially stacked on the insulating layer 15 made of an organic material. The metal layer ML1 is made of titanium. The metal layer ML1 of the terminal TM2 is arranged on the insulating layer 15 to be in tight contact with the insulating layer 15. The metal layer ML2 is made of aluminum. The metal layer ML2 is arranged on the metal layer ML1 to be in tight contact with the metal layer ML3. The metal layer ML3 is made of titanium. The metal layer ML3 is arranged on the metal layer ML2 to be in tight contact with the metal layer ML2. The metal layer ML3 of the terminal TM2 is bonded to the cap film CP2 at the bottom of the opening 16H2. The metal layer ML1 of the terminal TM2 is bonded to the metal layer ML3 of the conductor pattern MP2 at the bottom of the contact hole CH2.

The metal layer ML1, the metal layer ML2, and the metal layer ML3 of the terminal TM2 are the same as the metal layer ML1, the metal layer ML2, and the metal layer ML3 of the terminal TM1 described in FIG. 6, respectively, and therefore, are not repeatedly described.

The cap film CP2 includes the metal film MF1 made of titanium and bonded to the metal layer ML3 at the bottom of the opening 16H2. In the example of FIG. 9, the cap film CP2 includes the metal film MF2, the metal film MF3, and the metal film MF4 which are stacked on the metal film MF1. The metal film MF1, the metal film MF2, the metal film MF3, and the metal film MF4 of the cap film CP2 are the same as the metal film MF1, the metal film MF2, the metal film MF3, and the metal film MF4 described in FIG. 6, respectively, and therefore, are not repeatedly described.

However, the cap film CP2 is different from the cap film CP1 illustrated in FIG. 6 in that a part of the metal film MF1 (and a part of the metal film MF2) is embedded in the contact hole CH2.

### <Method of Manufacturing Electronic Apparatus>

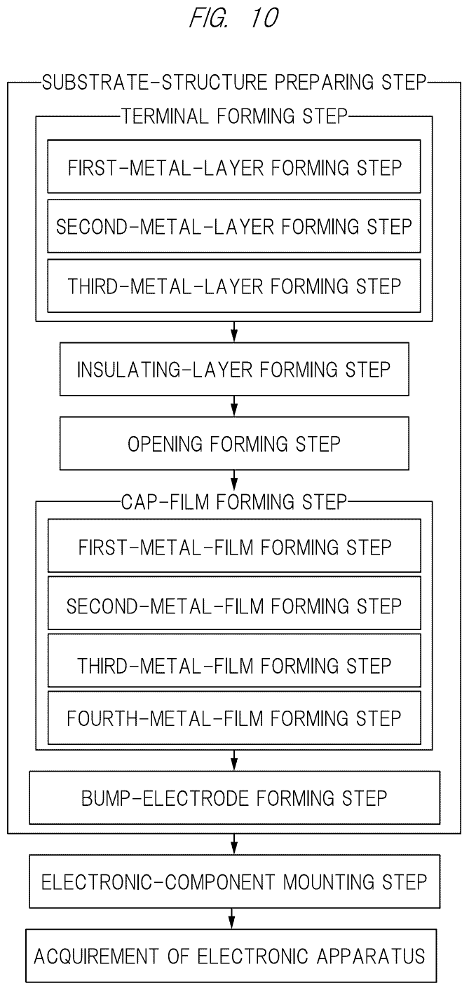

Next, a method of manufacturing the display apparatus of FIG. 4 will be described as a method of manufacturing an electronic apparatus according to the present embodiment. FIG. 10 is an explanatory diagram illustrating a flow example of steps of the method of manufacturing the display apparatus according to one embodiment of the electronic apparatus. As illustrated in FIG. 10, the method of manufacturing the electronic apparatus according to the present embodiment includes a substrate-structure preparing step, a bump-electrode forming step, and an electronic-component mounting step. If a substrate structure provided before the mounting of the electronic component is shipped as a semi-product, the electronic-component mounting step may be omitted.

In the substrate-structure preparing step, the substrate structure SUB1 provided before the formations of the bump electrode 30 and the bump electrode 31 illustrated in FIG. 4 is prepared. The substrate-structure preparing step includes a terminal forming step, an insulating-layer forming step, an opening forming step, and a cap-film forming step as illustrated in FIG. 10.

Although not illustrated in FIG. 10, the substrate-structure preparing step includes the following steps performed prior to the terminal forming step. That is, in the substrate-structure preparing step, first, the substrate 10 made of glass or resin is prepared (substrate preparing step). The substrate-structure preparing step includes a wiring-layer stacking step of stacking the members illustrated in FIG. 2 or 4 on the substrate 10. In the wiring-layer stacking step, the insulating layer 11, the wiring layer WL1, the insulating layer 12, the semiconductor device (such as the drive transistor DRT illustrated in FIG. 4), the insulating layer 13, the wiring layer WL2, the insulating layer 14, the wiring layer WL3, and the insulating layer 15 are sequentially stacked on the surface 10f of the substrate 10. The contact hole CH1 and the contact hole CH2 are formed in the insulating layer 15.

### <Terminal Forming Step>

In the example of FIG. 10, the terminal forming step includes a first-metal-layer forming step, a second-metal-layer forming step, and a third-metal-layer forming step.

In the first-metal-layer forming step, the metal layer ML1 in the lowermost layer of the terminal TM1 of FIG. 6 or the lowermost layer of the terminal TM2 of FIG. 9 is formed. The metal layer ML1 is the metal layer made of titanium and formed to be in tight contact with the insulating layer 15 as described above.

At the bottoms of the contact hole CH1 and the contact hole CH2 illustrated in FIG. 4, note that the metal layer ML1 (see FIG. 9) is bonded to the conductor pattern (the conductor pattern MP1 or the conductor pattern MP2 illustrated in FIG. 4) formed in the wiring layer WL3. If an oxide film is formed on the outermost surface (uppermost layer) of the wiring layer WL3 after the contact hole CH1 and the contact hole CH2 are formed, a process for removing this oxide film (such as the oxide film removal by bias sputtering) may be performed.

The metal layer ML3 made of titanium is formed in the outermost surfaces (uppermost layers) of the conductor pattern MP1 and the conductor pattern MP2 formed in the wiring layer WL3 as illustrated in FIG. 9. Thus, the titanium film is bonded to each of the bonding boundary between the conductor pattern MP1 and the terminal TM1 and the bonding boundary between the conductor pattern MP2 and the terminal TM2 illustrated in FIG. 4. Therefore, the titanium oxide films do not need to be completely removed. Therefore, even if the oxide film is removed by bias sputtering, the collision of the plasma with the wiring layer WL3 can be adjusted with energy preventing the formation of the voids 32 (see FIG. 32) as described above.

Next, in the second-metal-layer forming step, the metal layer ML2 configuring the terminal TM1 of FIG. 6 or the terminal TM2 of FIG. 9 is formed. As described above, the metal layer ML2 is the metal layer made of aluminum and formed to be in tight contact with the metal layer ML1. In a modification example of the present embodiment, when the metal layer ML1 is not to be formed, the first-metal-layer forming step of FIG. 10 is omitted. In this case, the metal layer ML2 made of aluminum is formed to be in tight contact with the insulating layer 15.

Next, in the third-metal-layer forming step, the metal layer ML3 configuring the terminal TM1 of FIG. 6 or the terminal TM2 of FIG. 9 is formed. As described above, the metal layer ML3 is the metal layer made of titanium and formed to be in tight contact with the metal layer ML2.

### <Insulating-Layer Forming Step>

Next, in the insulating-layer forming step of FIG. 10, the insulating layer 16 is formed as illustrated in FIG. 11. FIG. 11 is an enlarged cross-sectional view illustrating the insulating-layer forming step of FIG. 10.

In the insulating-layer forming step, the insulating layer 16 is formed to cover the terminal TM1 and the terminal TM2. The insulating layer 16 is the inorganic insulating film made of silicon nitride or the like as described above. Thus, a flattening function of the insulating layer 16 for the surface irregularity is lower than that of the insulating layer 15 that is the organic insulating film. Consequently, the insulating layer 16 has the upper face with the surface irregularity along the surface irregularity of the wiring layer WL4 formed on the insulating layer 15.

### <Opening Forming Step>

Next, in the opening forming step of FIG. 10, the opening 16H1 and the opening 16H2 are formed in the insulating layer 16 as illustrated in FIG. 12. FIG. 12 is an enlarged cross-sectional view illustrating the opening forming step of FIG. 10.

In the opening forming step, a part of the terminal TM1 is exposed from the insulating layer 16 by the formation of the opening 16H1. In the opening forming step, a part of the terminal TM2 is exposed from the insulating layer 16 by the formation of the opening 16H2.

A method of forming the opening 16H1 and the opening 16H2 is, for example, the following method. First, a resist mask not illustrated is formed, and then, the openings are formed by photolithography at positions of the resist mask, the positions overlapping regions where the opening 16H1 and the opening 16H2 are to be formed. Next, the insulating layer 16 exposed at the openings of the resist mask from the resist mask is removed by etching. As a result, the opening 16H1 and the opening 16H2 are formed. Then, the insulating layer 16 illustrated in FIG. 12 is provided by the removal of the resist mask.

### <Cap-Film Forming Step>

Next, in the cap-film forming step of FIG. 10, the cap film CP1 (see FIG. 6) and the cap film CP2 (see FIG. 9) described in FIGS. 4 to 9 are formed. A method of forming the cap film CP1 connected to the terminal TM1 will be described below as a representative example. Note that the cap film CP2 connected to the terminal TM2 of FIG. 9 can be formed by the same method as described below. The following explanation for each step is applicable while the “terminal TM1” is replaced with the “terminal TM2”, the “cap film CP1” is replaced with the “cap film CP2”, and the “opening 16H1” is replaced with the “opening 16H2”. The cap film CP1 and the cap film CP2 are formed by the same steps, and therefore, can be collectively formed.

In the example of FIG. 10, the cap-film forming step includes a first-metal-film forming step, a second-metal-film forming step, a third-metal-film forming step, and a fourth-metal-film forming step.

In the first-metal-film forming step, the metal film MF1 made of titanium is formed to be bonded with the metal layer ML3 of the terminal TM1 at the bottom of the opening 16H1 as illustrated in FIG. 13. FIG. 13 is an enlarged cross-sectional view illustrating the first-metal-film forming step of FIG. 10.

In the example of FIG. 13, first, a resist film 40 is formed to cover the insulating layer 16, and then, an opening is formed in the resist film 40 in a region where the metal film MF1 is to be formed. The region where the metal film MF1 is to be formed includes the entire opening 16H1 and its peripheral region.

Next, the metal film MF1 is selectively formed by use of the resist film 40 as a mask. As a method of forming the metal film MF1, for example, a sputtering method is exemplified. When the metal film MF1 is formed by the sputtering method, the metal film MF1 is formed also on the resist film 40, However, the metal film MF1 formed on the resist film 40 can be removed together with the resist film 40.

As described above, the titanium film is bonded to the bonding boundary between the terminal TM1 and the metal film MF1. Thus, the titanium oxide film at the bonding boundary may not be completely removed. Therefore, even if the oxide film is removed by bias sputtering, the collision of the plasma with the terminal TM1 can be adjusted with energy preventing the formation of the voids 32 (see FIG. 32) as described above.

The metal film MF1 includes the contact portion CPc totally covering the portion of the metal layer ML3 of the terminal TM1, the portion being exposed at the bottom of the opening 16H1 from the insulating layer 16. As described in FIG. 5, the metal film MF1 includes the peripheral portion CPp outside the opening 16H1. The peripheral portion CPp is formed to continuously surround the contact portion CPc in plan view.

As illustrated in FIG. 13, in this step, the thickness TF1 of the metal film MF1 is preferably larger than the thickness TL3 of the metal layer ML3.

In the second-metal-film forming step of FIG. 10, the metal film MF2 made of aluminum is formed on the metal film MF1 to be in tight contact with the metal film MF1 as illustrated in FIG. 14. FIG. 14 is an enlarged cross-sectional view illustrating the second-metal-film forming step of FIG. 10.

In the example of FIG. 14, the metal film MF2 is stacked while the metal film MF1 is formed inside the opening in the resist film 40. As a method of forming the metal film MF2, for example, a sputtering method is exemplified. When the metal film MF2 is formed by the sputtering method, the metal film MF2 is formed also on the resist film 40. However, the metal film MF2 formed on the resist film 40 can be removed together with the resist film 40.

This step is performed while the resist film 40 is left. Thus, the side surface of the metal film MF1, the side surface being in tight contact with the resist film 40, is exposed from the metal film MF2.

In the third-metal-film forming step described below, the metal film MF2 is eroded by the copper plating solution such that the thickness of the metal film MF2 is reduced, and thus, the metal film MF2 is preferably previously made thick. In the example of FIG. 14, the thickness TF2 of the metal film MF2 is larger than the thickness TF1 of the metal film MF1.

A process after the second-metal-film forming step illustrated in FIG. 10 and before the third-metal-film forming step includes a step of removing the resist film 40 illustrated in FIG. 14 and a step of removing the oxide film formed on the metal film MF2 illustrated in FIG. 14. To a method of removing the resist film 40, for example, an etching process is applicable. To a method of removing the oxide film on the metal film MF2, for example, a zincate treatment is applicable.

In the third-metal-film forming step of FIG. 10, the metal film MF3 made of copper is formed on the metal film MF2 to be in tight contact with the metal film MF2 as illustrated in FIG. 15. FIG. 15 is an enlarged cross-sectional view illustrating the third-metal-film forming step of FIG. 10.

The metal film MF3 is formed by an electroplating method. In the electroplating method, a metal film is selectively formed on a surface of a plating target member by making contact of the plating target member with the plating solution while the plating target member is conducted. At this time, the metal film MF2 made of aluminum is eroded by the copper plating solution such that the thickness TF2 of the metal film MF2 is reduced.

In the present embodiment, the opening 16H1 of the insulating layer 16 is totally covered with the metal film MF1. Thus, even if a part or the entire of the metal film MF2 is eroded by the plating solution in the third-metal-film forming step, the contact between the plating solution and the terminal TM1 can be prevented.

As described in FIG. 14, when the thickness TF2 of the metal film MF2 is previously made thick, the entire metal film MF2 can be prevented from being eroded by the plating solution.

The present embodiment employs countermeasures against the lost metal film MF2 due to the plating solution in the step of forming the metal film MF3 made of copper by the electroplating method. Thus, the metal film MF3 made of copper can be made thick. Consequently, resistance of the electrical connection portion between the bump electrode 30 of FIG. 6 and the terminal TM3 can be decreased.

This step is performed while the resist film 40 (see FIG. 14) is removed as illustrated in FIG. 15. The metal film formed by the electroplating method is isotropically grown on the surface of the metal film making contact with the plating solution. Thus, the metal film MF3 is formed to totally cover the metal film MF1 and the metal film MF2.

In the fourth-metal-film forming step of FIG. 10, the metal film MF4 made of nickel is formed on the metal film MF3 to be in tight contact with the metal film MF3 as illustrated in FIG. 16. FIG. 16 is an enlarged cross-sectional view illustrating the fourth-metal-film forming step of FIG. 10.

The metal film MF4 is formed by the electroplating method. Thus, the metal film MF4 is formed to totally cover the metal film MF3. Since the metal film MF4 made of nickel is formed to totally cover the metal film MF3 made of copper, the bonding strength between the cap film CP1 and the bump electrode 30 (see FIG. 5) can be improved.

The cap film CP1 is formed by the above steps.

### <Bump-Electrode Forming Step>

Next, in the bump-electrode forming step of FIG. 10, the bump electrode 30 and the bump electrode 31 (see FIG. 9) described in FIGS. 4 to 9 are formed. A method of forming the bump electrode 30 connected to the cap film CP1 illustrated in FIG. 6 will be described below as a representative example. Note that the bump electrode 31 connected to the cap film CP2 illustrated in FIG. 9 can be formed by the same method as described below. The following explanation for each step is applicable while the “terminal TM1” is replaced with the “terminal TM2”, the “cap film CP1” is replaced with the “cap film CP2”, and the “opening 16H1” is replaced with the “opening 16H2”. Note that the bump electrode 30 and the bump electrode 31 are formed by the same steps, and therefore, can be collectively formed.

In the bump-electrode forming step, the bump electrode 30 is formed on the cap film CP1 as illustrated in FIG. 6. In the present embodiment, the bump electrode 30 is formed by the electroplating method while the terminal TM1 is conducted. The bump electrode 30 is made of, for example, tin (solder). When the bump electrode 30 is formed by the electroplating method, the bump electrode 30 can be selectively formed on a portion of the cap film CP1, the portion making contact with the plating solution. Thus, a large-scale exposure apparatus such as large-sized stepper does not need to be additionally prepared.

By this step, the bump electrode 30 can be formed to cover the opening 16H1 of the insulating layer 16. The cap film CP1 intervenes between the bump electrode 30 and the terminal TM1.

The substrate structure SUB1 (see FIG. 4) provided before the mounting of the electronic components may be shipped as a semi-product. In this case, the electronic-component mounting step of FIG. 10 is omitted, and the substrate structure SUB1 of FIG. 6 is subjected to necessary inspections and is packed, and then, is ready to be shipped. That is, the substrate structure SUB1 as the electronic apparatus is provided by the bump-electrode forming step of FIG. 10.

Next, in the electronic-component mounting step of FIG. 10, after the bump-electrode forming step, each of the bump electrode 30 and the bump electrode 31 is electrically connected to the electronic component (the LED element 20 in the example of FIG. 4) as illustrated in FIG. 4. In this step, the bump electrode 30 and the bump electrode 31 are softened by, for example, laser irradiation. As a result, the bump electrode 30 is connected to the anode electrode 20EA of the LED element 20 while the bump electrode 31 is connected to the cathode electrode 20EC of the LED element 20. Note that the solder film may be previously formed on each of the anode electrode 20EA and the cathode electrode 20EC of the LED element 20 of FIG. 4 before this step. In this case, the bump electrodes 30 and 31 made of solder and the solder film formed on the electrode can be easily unified.

### <Modification Examples of Cap Film>

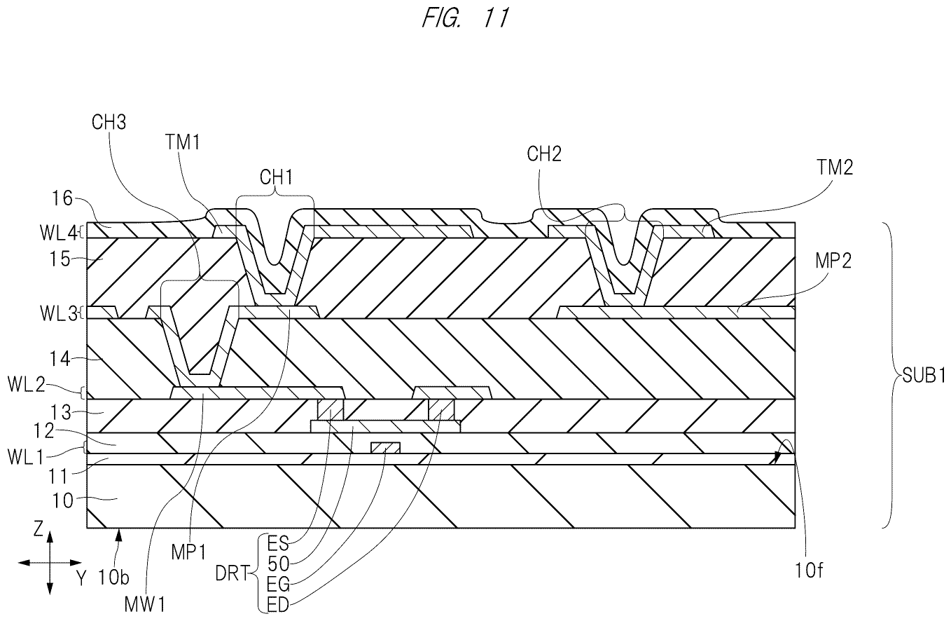

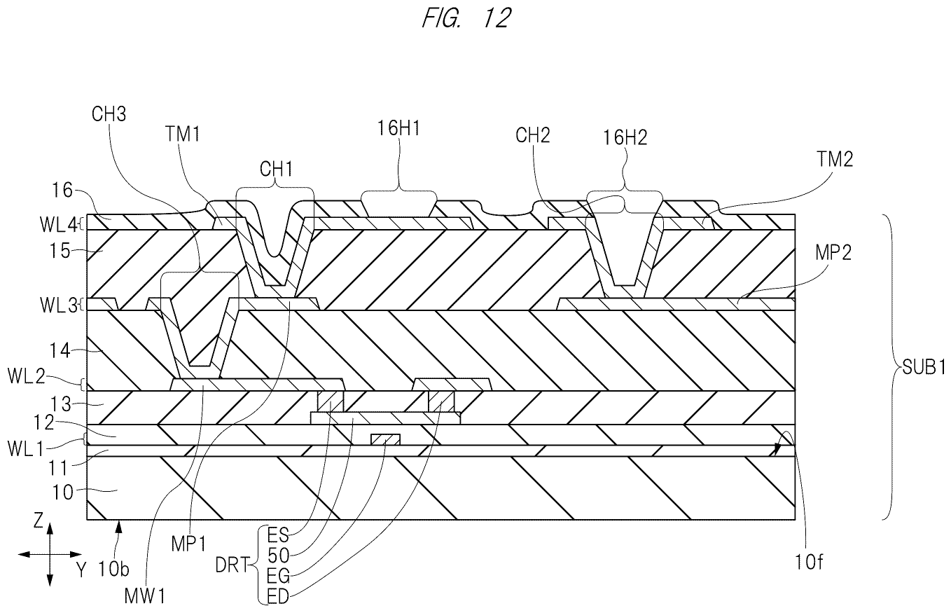

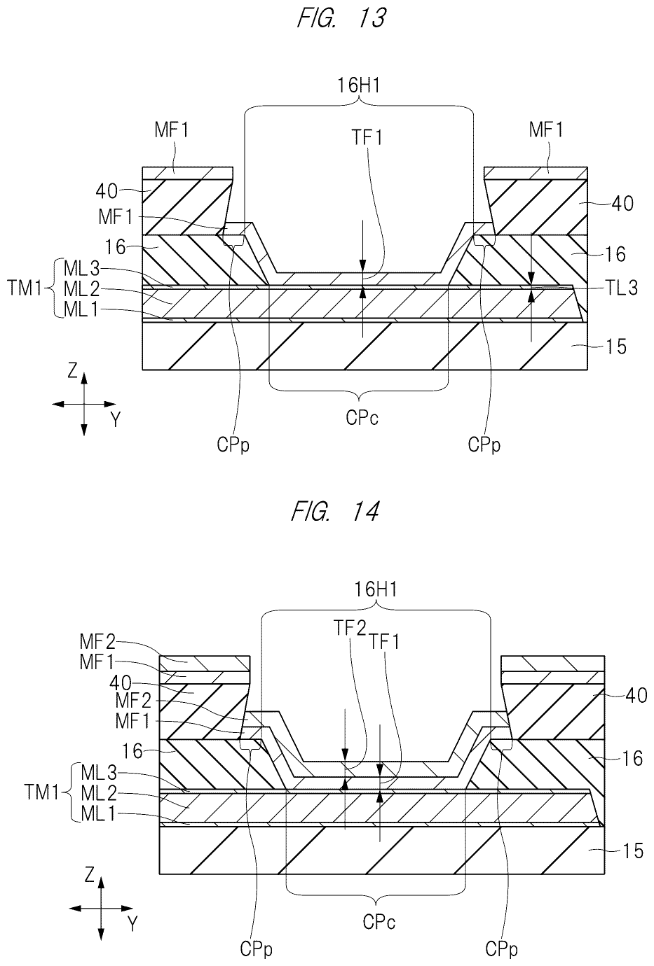

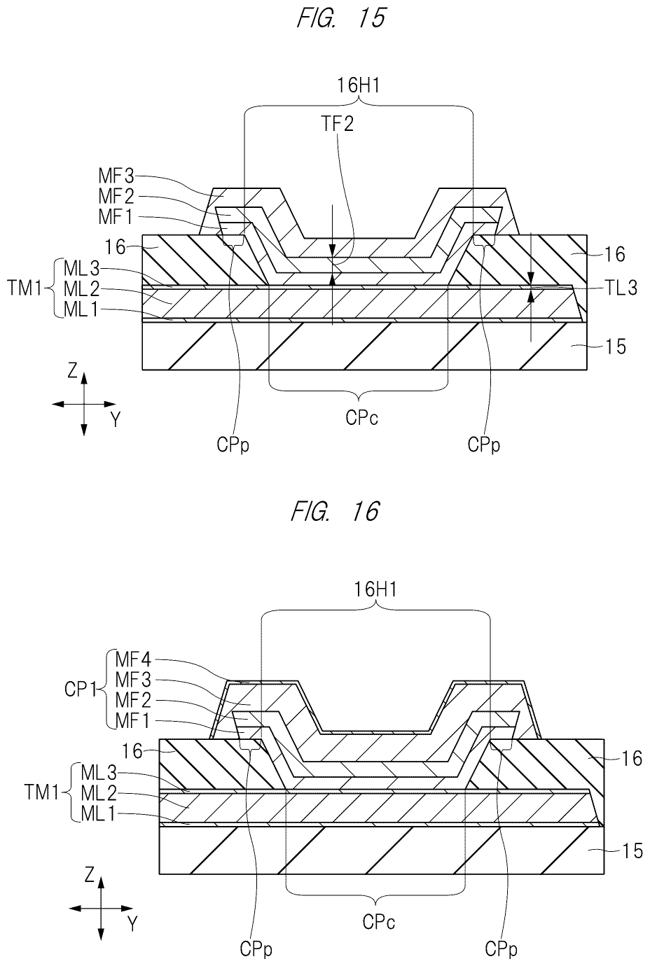

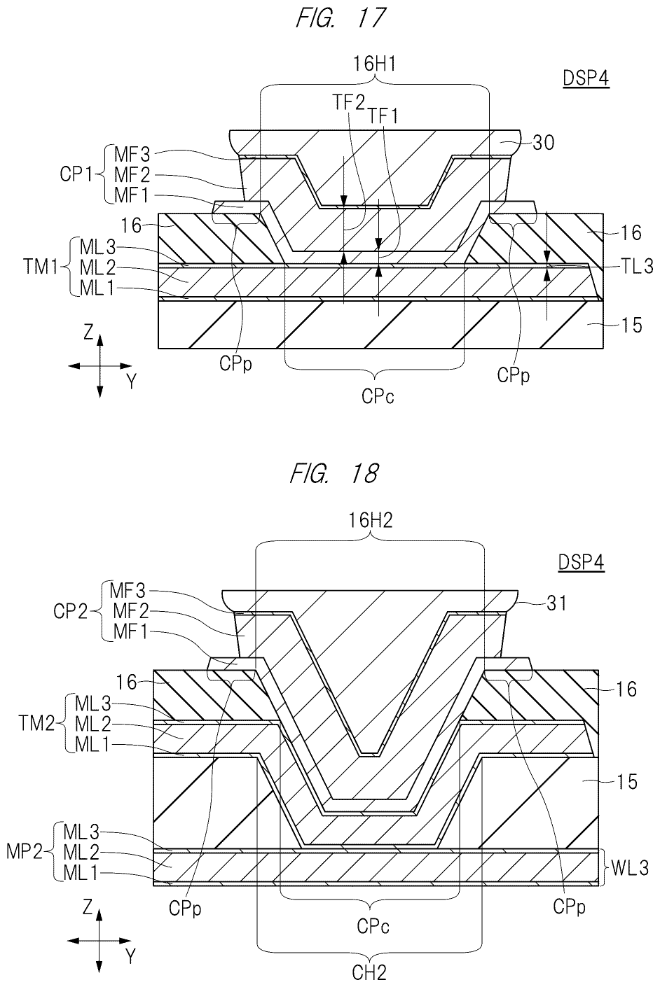

Next, modification examples of the cap film will be described. FIG. 17 is an enlarged cross-sectional view illustrating a modification example of FIG. 6. FIG. 18 is an enlarged cross-sectional view illustrating a modification example of FIG. 9.

A display apparatus DSP4 illustrated in FIGS. 17 and 18 is different from the display apparatus DSP1 illustrated in FIGS. 6 and 9 in the following points.

First, each of the cap film CP1 and the cap film CP2 included in the display apparatus DSP4 is of a three-layer structure of the metal film MF1 made of titanium, the metal film MF2 made of copper, and the metal film MF3 made of nickel.

Also, a part (specifically, the side surface) of each of the cap film CP1 and the cap film CP2 included in the display apparatus DSP4 is exposed from the bump electrode 30 or the bump electrode 31.

Also, in the examples of FIGS. 17 and 18, a part of the metal film MF1 is exposed from the metal film MF2 and the metal film MF3.

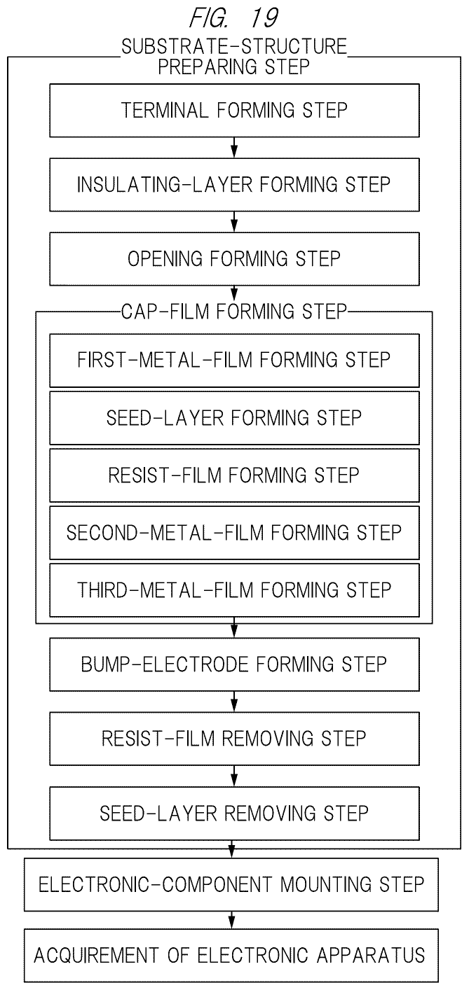

A method of manufacturing the display apparatus DSP4 illustrated in FIGS. 17 and 18 is different from the method of manufacturing the display apparatus DSP1 (see FIG. 4) described in FIGS. 10 to 16 in the following points. FIG. 19 is an explanatory diagram illustrating a flow example of steps of the method of manufacturing the display apparatus according to a modification example of FIG. 10. Note that a terminal forming step of FIG. 19 is the same as the terminal forming step of FIG. 10, and therefore, each of the first-metal-layer forming step, the second-metal-layer forming step, and the third-metal-layer forming step illustrated in FIG. 10 is not illustrated in FIG. 19. The manufacturing method of FIG. 19 is different in the cap-film forming step from the manufacturing method of FIG. 10. The manufacturing method of FIG. 19 is different from the manufacturing method of FIG. 10 in that a resist-film removing step and a seed-layer removing step are performed after the bump-electrode forming step and before the electronic-component mounting step.

The steps different from the steps of FIG. 10 will be described below. A method of forming the cap film CP1 connected to the terminal TM1 of FIG. 17 and a method of forming the bump electrode 30 connected to the cap film CP1 will be described below as representative examples. Note that the cap film CP2 connected to the terminal TM2 of FIG. 18 can be formed by the same method as described below. The following explanation for each step is applicable while the “terminal TM1” is replaced with the “terminal TM2”, the “cap film CP1” is replaced with the “cap film CP2”, the “opening 16H1” is replaced with the “opening 16H2”, and the “bump electrode 30” is replaced with the “bump electrode 31”.

The cap-film forming step of FIG. 19 includes the first-metal-film forming step, the seed-layer forming step, the resist-film forming step, the second-metal-film forming step, and the third-metal-film forming step.

In the first-metal-film forming step, as similar to the example of FIG. 13, the metal film MF1 made of titanium is formed to be bonded with the metal layer ML3 of the terminal TM1 at the bottom of the opening 16H1. In this modification example, note that the resist film 40 of FIG. 13 is removed after the first-metal-film forming step and before the seed-layer forming step.

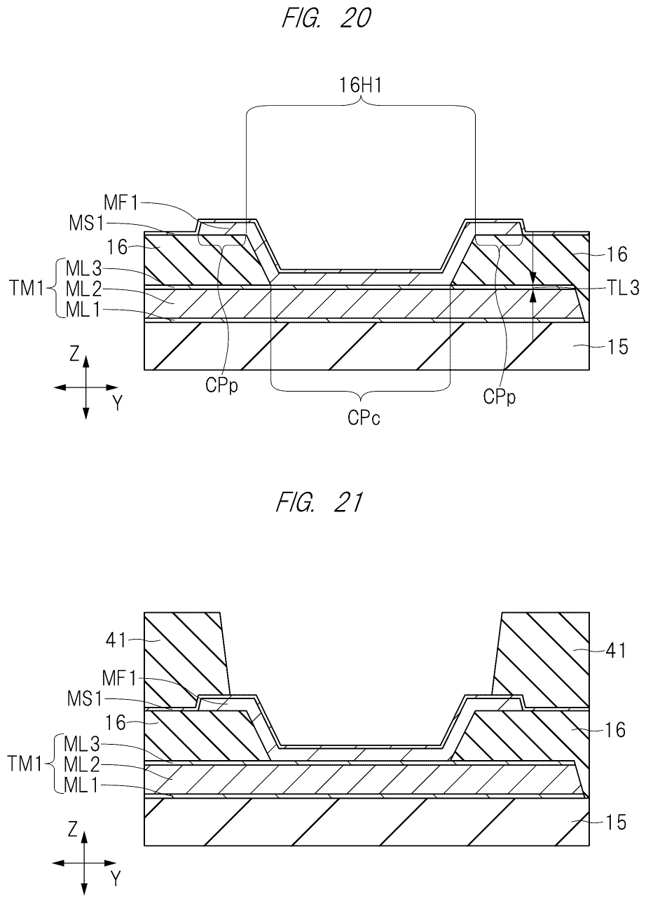

In the seed-layer forming step of FIG. 19, a seed layer (copper seed layer) MS1 made of copper is formed on the metal film MF1 and on the insulating layer 16 to in tight contact with the metal film MF1 and the insulating layer 16 as illustrated in FIG. 20. FIG. 20 is an enlarged cross-sectional view illustrating the seed-layer forming step of FIG. 19.

The seed-layer forming step is performed while the resist film 40 of FIG. 13 is removed as illustrated in FIG. 20. The seed layer MS1 is a metallic thin film made of copper and is formed by a sputtering method. Thus, as illustrated in FIG. 20, in this step, the seed layer MS1 is formed to totally cover the insulating layer 16 and the metal film MF1.

Incidentally, in this modification example, the metal film MF1 made of titanium and the seed layer MS1 made of copper are in tight contact with each other. Thus, the process using the bias sputtering method described above is preferably performed as a step of removing the titanium oxide film formed on the surface of the metal film MF1 or a step of removing contaminants such as carbon. The bias sputtering method is a process of making the collision of the plasma with the process target portion as described above.

In this modification example, the portion (the contact portion CPc) of the terminal TM1, the portion being exposed at the opening 16H1 from the insulating layer 16, is totally covered with the metal film MF1. Thus, even if strong energy is applied to the metal film MF1 by the bias sputtering method, the formation of the voids 32 described in FIG. 8 can be prevented. In order to prevent the metal film MF1 from being burned and lost by the bias sputtering method, the thickness TF1 of the metal film MF1 is preferably larger than the thickness TL3 of the metal layer ML3 of the terminal TM1 as illustrated in FIG. 17.

In the resist-film forming step of FIG. 19, a resist film 41 is formed to cover the seed layer MS1, and then, an opening is formed in the resist film 41 as illustrated in FIG. 21. FIG. 21 is an enlarged cross-sectional view illustrating the resist-film forming step of FIG. 19. At least a part of the portion of the seed layer MS1, the portion overlapping the metal film MF1, is exposed from the resist film 41.

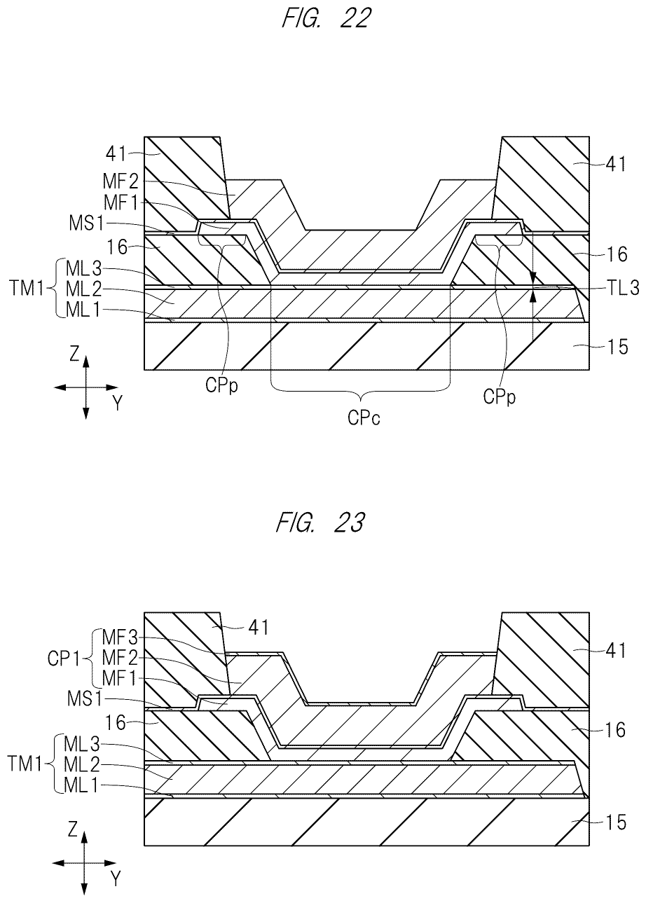

In the second-metal-film forming step of FIG. 19, the metal film MF2 made of copper is formed on the seed layer MS1 to be in tight contact with the seed layer MS1 as illustrated in FIG. 22. FIG. 22 is an enlarged cross-sectional view illustrating the second-metal-film forming step of FIG. 19.

In this step, the metal film MF2 is formed by, for example, the electroplating method. The electroplating method enables the metal film to be thicker than the sputtering method. Thus, the thickness TF2 of the metal film MF2 is larger than the thickness TF1 of the metal film MF1 as illustrated in FIG. 17.

This step is performed while the resist film 41 is formed on the insulating layer 16 as illustrated in FIG. 22. Thus, the metal film MF2 is selectively formed on the portion of the surface of the seed layer MS1, the portion being exposed inside the opening in the resist film 41 from the resist film 41. A part of the metal film MF1 is exposed from the metal film MF2 as illustrated in FIG. 17.

In the third-metal-film forming step of FIG. 19, the metal film MF3 made of nickel is formed on the metal film MF2 to be in tight contact with the metal film MF2 as illustrated in FIG. 23. FIG. 23 is an enlarged cross-sectional view illustrating the third-metal-film forming step of FIG. 19.

In this step, the metal film MF3 is formed by, for example, the electroplating method. This step is performed while the resist film 41 is formed on the insulating layer 16 as similar to the second-metal-film forming step. Thus, a part of the metal film MF1 is exposed from the metal film MF3 as illustrated in FIG. 17.

Next, in the bump-electrode forming step of FIG. 19, the bump electrode 30 is formed on the cap film CP1 as illustrated in FIG. 24. FIG. 24 is an enlarged cross-sectional view illustrating the bump-electrode forming step of FIG. 19. In this modification example, the bump electrode 30 is formed by the electroplating method while the terminal TM1 is conducted. The bump electrode 30 is made of, for example, tin (solder).

This step is performed while the resist film 41 is formed on the insulating layer 16 as similar to the second-metal-film forming step and the third-metal-film forming step. Thus, a part of each of the metal film MF1 and the metal film MF2 is exposed from the bump electrode 30 as illustrated in FIG. 17.

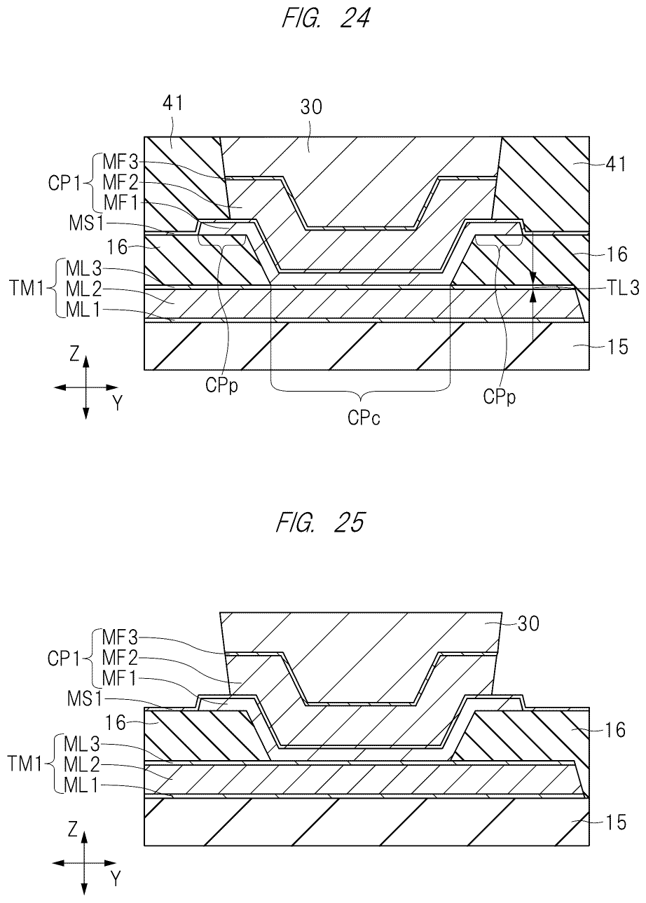

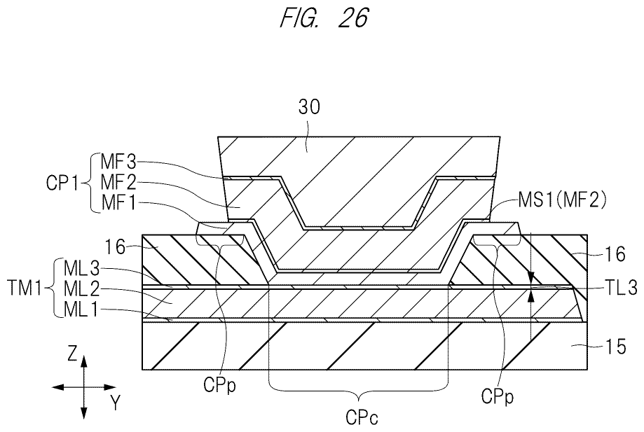

Next, in the resist-film removing step of FIG. 19, the resist film 41 (see FIG. 24) is removed as illustrated in FIG. 25. FIG. 25 is an enlarged cross-sectional view illustrating the resist-film removing step of FIG. 19. As a method of removing the resist film 41, for example, etching is performed.

Next, in the seed-layer removing step of FIG. 19, a part of the seed layer MS1 is removed as illustrated in FIG. 26. FIG. 26 is an enlarged cross-sectional view illustrating the seed-layer removing step of FIG. 19. The seed layer MS1 is removed by etching. Note that etchant used in the seed-layer removing step is preferably selected to have a higher etching rate for copper than an etching rate for titanium.

In this case, a part of the metal film MF2 is etched together with the seed layer MS1. However, since the thickness of the metal film MF2 can be made much larger than the thickness of the seed layer MS1, the metal film MF2 can be prevented from being entirely removed in this step.

The metal film MF1 made of titanium is in tight contact with the opening 16H1 (see FIG. 20) of the insulating layer 16. Thus, the voids can be prevented from being formed inside the opening due to intrusion of the etchant into the opening.

Note that a part of the seed layer MS1, the part intervening between the metal film MF2 and the metal film MF1, is left. However, both the seed layer MS1 and the metal film MF2 are metal films made of copper, and therefore, a boundary therebetween may not be clear. Thus, the left part of the seed layer MS1, which is not removed in this step, can be regarded as a part of the metal film MF2 as illustrated in FIG. 26.

The embodiments and representative modification examples have been described above. However, the above-described techniques are applicable to various modification examples in addition to the exemplified modification examples. For example, the above modification examples may be combined.

In the scope of the idea of the present invention, various modification examples and alteration examples could have been easily anticipated by those who are skilled in the art, and it would be understood that these various modification examples and alteration examples are within the scope of the present invention. For example, the ones obtained by appropriate addition, removal, or design-change of the components to/from/into each of the above-described embodiments by those who are skilled in the art or obtained by addition, omitting, or condition-change of the step to/from/into each of the above-described embodiments are also within the scope of the present invention as long as they include the idea of the present invention.

The present invention is applicable to an electronic apparatus such as a display apparatus.

What is claimed is:

1. An electronic apparatus comprising:
a first substrate;
a first terminal arranged on the first substrate;
a first insulating layer which is an inorganic insulating layer made of an inorganic material and which covers the first terminal;
a first opening formed in the first insulating layer;
a first cap film connected to the first terminal at the first opening; and
a first bump electrode electrically connected to the first terminal through the first cap film,
wherein the first terminal includes:
a first metal layer made of aluminum; and
a second metal layer which is made of titanium, which is arranged on the first metal layer to be in tight contact with the first metal layer, and which is bonded to the first cap film at the first opening,
the first cap film includes a first metal film which is made of titanium and which is bonded to the second metal layer at the first opening,
the first metal film includes:
a contact portion which totally covers a portion of the second metal layer of the first terminal, the portion being exposed at the first opening from the first insulating layer; and
a peripheral portion which is arranged outside the first opening and which continuously surrounds the contact portion in plan view, and
the first insulating layer intervenes between the peripheral portion of the first metal film and the first terminal.

2. The electronic apparatus according to claim 1,
wherein the first cap film further includes a second metal film stacked on the first metal film, and
the second metal film is made of aluminum or copper.

3. The electronic apparatus according to claim 2,
wherein the first cap film further includes a third metal film stacked on the second metal film,
the second metal film is made of aluminum, and
the third metal film is made of copper and totally covers the first metal film and the second metal film.

4. The electronic apparatus according to claim 3,
wherein the first cap film further includes a fourth metal film stacked on the third metal film,
a part of the first metal film is exposed from the second metal film, and
the fourth metal film is made of nickel and totally covers the third metal film.

5. The electronic apparatus according to claim 2,
wherein the first cap film further includes a third metal film stacked on the second metal film,
the second metal film is made of copper, and
the third metal film is made of nickel.

6. The electronic apparatus according to claim 5,
wherein a part of the first metal film is exposed from the second metal film and the third metal film.

7. The electronic apparatus according to claim 1,
wherein the first metal film of the first cap film is thicker than the second metal layer of the first terminal.

8. The electronic apparatus according to claim 2,
wherein the first metal film of the first cap film is thicker than the second metal layer of the first terminal and is thinner than the second metal film.

9. The electronic apparatus according to claim 1,
wherein the first terminal further includes a third metal layer made of titanium, and
the first metal layer is arranged on the third metal layer to be in tight contact with the third metal layer.

10. The electronic apparatus according to claim 9,
wherein the third metal layer is arranged on a second insulating layer made of an organic material to be in tight contact with the second insulating layer.

11. A method of manufacturing an electronic apparatus, comprising steps of:
(a) forming a first terminal on a first substrate;
(b) forming a first insulating layer made of an inorganic material to cover the first terminal;
(c) forming a first opening in the first insulating layer to expose a part of the first terminal from the first insulating layer;
(d) forming a first cap film to cover the first opening; and
(e) forming a bump electrode on the first cap film, wherein the step (a) includes steps of:
(a1) forming a first metal layer made of aluminum; and
(a2) forming a second metal layer made of titanium on the first metal layer to be in tight contact with the first metal layer,
the step (d) includes a step of
(d1) forming a first metal film made of titanium to be bonded to the second metal layer at the first opening,
the first metal film includes:
a contact portion which totally covers a portion of the second metal layer of the first terminal, the portion being exposed at the first opening from the first insulating layer; and
a peripheral portion which is arranged outside the first opening and which continuously surrounds the contact portion in plan view, and
the first insulating layer intervenes between the peripheral portion of the first metal film and the first terminal.

12. The method of manufacturing the electronic apparatus according to claim 11,
wherein the step (d) further includes a step of
(d2) stacking a second metal film made of aluminum or copper on the first metal film.

13. The method of manufacturing the electronic apparatus according to claim 12,
wherein the second metal film is made of aluminum,
the step (d) further includes a step of
(d3) stacking a third metal film made of copper on the second metal film, and
the third metal film is formed to totally cover the first metal film and the second metal film.

14. The method of manufacturing the electronic apparatus according to claim 13,
wherein the step (d) further includes a step of
(d4) stacking a fourth metal film made of nickel on the third metal film, and
the fourth metal film is formed to totally cover the third metal film.

15. The method of manufacturing the electronic apparatus according to claim 12,
wherein the second metal film is made of copper, and
the step (d) further includes a step of
(d3) stacking a third metal film made of nickel on the second metal film.

16. The method of manufacturing the electronic apparatus according to claim 15,
wherein a part of the first metal film is exposed from the second metal film and the third metal film.

17. The method of manufacturing the electronic apparatus according to claim 11,
wherein, in the step (d1), the first metal film of the first cap film is formed to be thicker than the second metal layer of the first terminal.
